(19) United States
(12) Patent Application Publication
(10) Pub. No.: US 2007/0284565 A1
(43) Pub. Date: Dec. 13, 2007

(54) LED DEVICE WITH RE-EMITTING SEMICONDUCTOR CONSTRUCTION AND OPTICAL ELEMENT

(75) Inventors: Catherine A. Leatherdale, Woodbury, MN (US); Andrew J. Ouderkirk, Woodbury, MN (US); Michael A. Haase, St. Paul, MN (US); Thomas J. Miller, Woodbury, MN (US); Dong Lu, Woodbury, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/761,078

(22) Filed: Jun. 11, 2007

Related U.S. Application Data
(60) Provisional application No. 60/804,541, filed on Jun. 12, 2006.
(60) Provisional application No. 60/804,824, filed on Jun. 14, 2006.

(51) Int. Cl. H01L 29/06

(52) U.S. Cl. 257/13

(57) ABSTRACT

A light source includes an LED component having an emitting surface, and an optical element having an input surface in optical contact with the emitting surface. The LED component may be or include an LED such as an LED die capable of emitting light at a first wavelength, in combination with a re-emitting semiconductor construction which includes a second potential well not located within a pn junction. The optical element can be an extractor whose shape is converging, diverging, or a combination thereof.

### CROSS REFERENCE TO RELATED APPLICATIONS

This application claims the benefit of U.S. Provisional Patent Application No. 60/804541, filed Jun. 12, 2006, and U.S. Provisional Patent Application No. 60/804824, filed Jun. 14, 2006, the disclosures of which are incorporated by reference herein in their entirety.

The following co-owned and currently pending U.S. patent applications are incorporated herein by reference: U.S. Ser. No. 11/009217; U.S. Ser. No. 11/009241; U.S. Ser. No. 10/977577; U.S. Ser. No. 10/977225; U.S. Ser. No. 10/977248; U.S. Ser. No. 10/977241; U.S. Ser. No. 11/381518; U.S. Ser. No. 10/977241; U.S. Ser. No. 11/381518; U.S. Ser. No. 11/381293; U.S. Ser. No. 11/381324; U.S. Ser. No. 11/381329; U.S. Ser. No. 11/381332; and U.S. Ser. No. 11/381984.

### FIELD OF THE DISCLOSURE

The present invention relates to light sources. More particularly, the present invention relates to light sources that include a light emitting diode (LED), a re-emitting semiconductor construction, and an optical element such as an extractor as described herein.

### BACKGROUND OF THE DISCLOSURE

Light emitting diodes (LEDs) are solid-state semiconductor devices which emit light when an electrical current is passed between anode and cathode. Conventional LED's contain a single pn junction. The pn junction may include an intermediate undoped region; this type of pn junction may also be called a pin junction. Like non-light emitting semiconductor diodes, conventional LEDs pass an electrical current much more readily in one direction, i.e., in the direction where electrons are moving from the n-region to the p-region. When a current passes in the “forward” direction through the LED, electrons from the n-region recombine with holes from the p-region, generating photons of light. The light emitted by a conventional LED is monochromatic in appearance; that is, it is generated in a single narrow band of wavelengths. The wavelength of the emitted light corresponds to the energy associated with electron-hole pair recombination. In the simplest case, that energy is approximately the band gap energy of the semiconductor in which the recombination occurs.

Conventional LEDs may additionally contain one or more quantum wells at the pn junction which capture high concentrations of both electrons and holes, thereby enhancing light-producing recombination. Several investigators have attempted to produce an LED device which emits white light, or light which appears white to the 3-color perception of the human eye.

Some investigators report the purported design or manufacture of LEDs having multiple quantum wells within the pn junction, where the multiple quantum wells are intended to emit light at different wavelengths. The following references may be relevant to such technology: U.S. Pat. No. 5,851,905; U.S. Pat. No. 6,303,404; U.S. Pat. No. 6,504,171; U.S. Pat. No. 6,734,467; Damilano et al., Monolithic White Light Emitting Diodes Based on InGaN/GaN Multiple-Quantum Wells, Jpn. J. Appl. Phys. Vol. 40 (2001) pp. L918-L920; Yamada et al., Re-emitting semiconductor construction Free High-Luminous-Efficiency White Light-Emitting Diodes Composed of InGaN Multi-Quantum Well, Jpn. J. Appl. Phys. Vol. 41 (2002) pp. L246-L248; Dalmasso et al., Injection Dependence of the Electroluminescence Spectra of Re-emitting semiconductor construction Free GaN-Based White Light Emitting Diodes, phys. stat. sol. (a) 192, No. 1, 139-143 (2003).

Some investigators report the purported design or manufacture of LED devices which combine two conventional LEDs, intended to independently emit light at different wavelengths, in a single device. The following references may be relevant to such technology: U.S. Pat. No. 5,851,905; U.S. Pat. No. 6,734,467; U.S. Pat. Pub. No. 2002/0041148 A1; U.S. Pat. Pub. No. 2002/0134989 A1; and Luo et al., Patterned three-color ZnCdSe/ZnCdMgSe quantum-well structures for integrated full-color and white light emitters, App. Phys. Letters, vol. 77, no. 26, pp. 4259-4261 (2000).

Some investigators report the purported design or manufacture of LED devices which combine a conventional LED element with a chemical re-emitting semiconductor construction, such as yttrium aluminum garnet (YAG), which is intended to absorb a portion of the light emitted by the LED element and re-emit light of a longer wavelength. U.S. Pat. No. 5,998,925 and U.S. Pat. No. 6,734,467 may be relevant to such technology.

Some investigators report the purported design or manufacture of LEDs grown on a ZnSe substrate n-doped with I, Al, Cl, Br, Ga or In so as to create fluorescing centers in the substrate, which are intended to absorb a portion of the light emitted by the LED element and re-emit light of a longer wavelength. U.S. Pat. No. 6,337,536 and Japanese Pat. App. Pub. No. 2004-072047 may be relevant to such technology.

US Pat. Pub. No. 2005/0023545 (Camras et al.) is incorporated herein by reference.

### SUMMARY OF THE DISCLOSURE

The present application discloses, among other things, a light source comprising an LED component having an emitting surface, which LED component may be or comprise: i) an LED capable of emitting light at a first wavelength; and ii) a re-emitting semiconductor construction which comprises a second potential well not located within a pn junction. The LED and the re-emitting semiconductor construction may be part of a single die or chip, in which the LED is associated with a first potential well located within a pn junction, and the re-emitting semiconductor construction is associated with a second potential well not located within a pn junction. Alternatively, the LED and re-emitting semiconductor construction may be separate parts between which a light path is provided via one or more other light-transmissive components. The disclosed light sources also preferably include an optical element having an input surface and an output surface, the input surface being in optical contact with the emitting surface of the LED component. Such emitting surface can be a surface of the LED or a surface of the re-emitting semiconductor construction, but in many cases it is a surface of a relatively high refractive index material such as a semiconductor material or other substrate material such as Si, Ge, GaAs, InP, sapphire, SiC, ZnSe, or the like. To enhance the coupling of light out of the LED component, the optical element preferably also has a relatively high refractive index, e.g., at least 1.7, 1.8, 1.9, 2.0, 2.1, 2.2, 2.3, or 2.4 or more, at the wavelength of light emitted by the LED. The optical element may be an encapsulant that is formed in place over the LED component and substantially surrounds the LED component (or portions thereof), or it may be an “extractor” that is made separately and then brought into contact or close proximity with a surface of an LED component to couple or extract light therefrom and reduce the amount of light trapped within the component. The extractor or other optical element may have a diverging shape, to partially collimate light collected at the input surface, or a converging shape, to direct light collected at the input surface into a side-emitting pattern.

In some embodiments, the light source additionally comprises a patterned low index layer in optical contact with a first portion of the emitting surface, the patterned layer having a first refractive index; and the input surface of the optical element is in optical contact with a second portion of the emitting surface, the optical element having a second refractive index higher than the first refractive index. In some embodiments, the light source additionally comprises means for totally internally reflecting at least some of the light generated by the LED component back into the LED component, the reflecting means being in optical contact with a first portion of the emitting surface; and the input surface of the optical element being in optical contact with a second portion of the emitting surface different from the first portion. In some embodiments, the optical element comprises a first portion that comprises the input surface and that is composed of a first material, the optical element also comprising a second portion that comprises the output surface and that is composed of a second material; and wherein the first material has a refractive index greater than that of the second material. In some embodiments, the optical element is one of a plurality of optical elements, each such optical element having an input surface; wherein the optical elements are sized such that the input surfaces are spaced apart from each other and are in optical contact with different portions of the emitting surface.

In some embodiments, the optical element has a base, two converging sides, and two diverging sides, wherein the base is the input surface optically coupled to the emitting surface. In some embodiments, the optical element is optically coupled to the LED component and shaped to direct light emitted by the LED component to produce a side emitting pattern having two lobes. In some embodiments, the optical element has a base, an apex smaller than the base, and a converging side extending between the base and the apex, wherein the base is optically coupled to and is no greater in size than the emitting surface, and wherein the optical element directs light emitted by the LED component to produce a side emitting pattern. In some embodiments, the optical element has a base, an apex, and a converging side joining the base and the apex, and the base is optically coupled to the emitting surface, and the optical element comprises a first section including the base and that is composed of a first material, and a second section including the apex and that is composed of a second material. In some embodiments, the optical element has a first index of refraction and has a base, an apex, and a converging side joining the base and the apex, the base being optically coupled to and being no greater in size than the emitting surface, the light source also comprising a second optical element encapsulating the LED component and the first-named optical element, the second optical element having a second index of refraction lower than the first index of refraction. In some embodiments, the optical element has a first index of refraction and having a base, an apex residing over the emitting surface, and a converging side joining the base and the apex, the base being optically coupled to the emitting surface, the light source also comprising a second optical element encapsulating the LED component and the first-named optical element, the second optical element having a second index of refraction lower than the first index of refraction. In some embodiments, a second optical element encapsulating the LED component and the first optical element provides an increase in power extracted from the LED component compared to the power extracted by first optical element alone. In some embodiments, the optical element has a base, an apex, and a side joining the base and the apex, the base being optically coupled to and mechanically decoupled from the emitting surface.

Graphic display devices and illumination devices comprising the disclosed LED devices are also described.

These and other aspects of the present application will be apparent from the detailed description below. In no event, however, should the above summaries be construed as limitations on the claimed subject matter, which subject matter is defined solely by the attached claims, as may be amended during prosecution.

In this application:

with regard to a stack of layers in a semiconductor device, “immediately adjacent” means next in sequence without intervening layers, “closely adjacent” means next in sequence with one or a few intervening layers, and “surrounding” means both before and after in sequence;

“potential well” means a layer of semiconductor in a semiconductor device that has a lower conduction band energy than surrounding layers or a higher valence band energy than surrounding layers, or both;

“quantum well” means a potential well that is thin enough, typically 100 nm or less, so that quantization effects raise the electron-hole pair transition energy in the well;

“transition energy” means electron-hole recombination energy;

“lattice-matched” means, with reference to two crystalline materials, such as an epitaxial film on a substrate, that each material taken in isolation has a lattice constant, and that these lattice constants are substantially equal, typically not more than 0.2% different from each other, more typically not more than 0.1% different from each other, and most typically not more than 0.01% different from each other; and

“pseudomorphic” means, with reference to a first crystalline layer of given thickness and a second crystalline layer, such as an epitaxial film and a substrate, that each layer taken in isolation has a lattice constant, and that these lattice constants are sufficiently similar so that the first layer, in the given thickness, can adopt the lattice spacing of the second layer in the plane of the layer substantially without misfit defects.

It should be understood that, for any disclosed embodiment comprising n-doped and p-doped semiconductor regions, a further embodiment should be considered as disclosed herein wherein n doping is exchanged with p doping and vice-versa.

It should be understood that, where each of “potential well,” “first potential well,” “second potential well” and “third potential well” are recited herein, a single potential well may be provided or multiple potential wells, which typically share similar properties, may be provided. Likewise, it should be understood that, where each of “quantum well,” “first quantum well,” “second quantum well” and “third quantum well” are recited herein, a single quantum well may be provided or multiple quantum wells, which typically share similar properties, may be provided.

### BRIEF DESCRIPTION OF THE DRAWINGS

FIG. 1 is a flat-band diagram of conduction and valence bands of semiconductors in a construction. Layer thickness is not represented to scale;

FIG. 2 is a graph indicating lattice constant and band gap energy for a variety of II-VI binary compounds and alloys thereof;

FIG. 3 is a graph representing the spectrum of light emitted from a device;

FIG. 4 is a flat-band diagram of conduction and valence bands of semiconductors in a construction; layer thickness is not represented to scale;

FIGS. 5 and 6 are schematic sectional views of LED packages having a brightness enhancing layer;

FIGS. 7 and 8 are schematic sectional views of more LED packages having brightness enhancing layers, and tapered optical elements;

FIG. 9 is a graph showing modeled brightness and luminous output of an LED component as a function of the footprint size of the tapered element on the front emitting surface of the LED component;

FIGS. 10-12 are schematic sectional views showing LED packages utilizing compound taper elements, and FIG. 12 further shows multiple taper elements coupled to an LED component;

FIG. 13 is a schematic sectional view of another LED package having a brightness enhancing layer and multiple optical elements;

FIG. 14 is a schematic side view illustrating an optical element and LED component configuration;

FIGS. 15a-c are perspective views of additional optical elements;

FIG. 16 is a perspective view of a light source having another optical element;

FIGS. 17a-i are top views of additional optical elements;

FIGS. 18a-c are schematic front views illustrating alternative optical elements;

FIGS. 19a-e are schematic side views of additional light sources that incorporate optical elements and LED components;

FIGS. 20a-d are bottom views of optical element/LED component combinations;

FIG. 21 is a perspective view of an optical element and an LED component array; and

FIG. 22 is partial side view of another optical element/LED component combination.

### DETAILED DESCRIPTION

The present application discloses illumination devices that comprise an LED component, which component includes an LED in combination with a re-emitting semiconductor construction, and an optical element in optical contact with, or optically coupled to, an emitting surface of the LED component. The optical element is preferably of relatively high refractive index to enhance light coupling out of the LED component, and preferably is or includes an extractor but may also be or include an encapsulant. Typically the LED is capable of emitting light at a first wavelength and the re-emitting semiconductor construction is capable of absorbing light at that first wavelength and re-emitting light at a second wavelength. The re-emitting semiconductor construction comprises a potential well not located within a pn junction. The potential wells of the re-emitting semiconductor construction are typically but not necessarily quantum wells.

In typical operation, the LED emits photons in response to an electric current and the re-emitting semiconductor construction emits photons in response to the absorption of a portion of the photons emitted from the LED. If desired, the re-emitting semiconductor construction can additionally comprise an absorbing layer closely or immediately adjacent to the potential well. Absorbing layers typically have a band gap energy less than or equal to the energy of photons emitted by the LED and greater than the transition energy of the potential well(s) of the re-emitting semiconductor construction. In typical operation the absorbing layers assist absorption of photons emitted from the LED. The re-emitting semiconductor construction may additionally comprise at least one second potential well not located within a pn junction having a second transition energy not equal to the transition energy of the first potential well. In some embodiments, the LED is a UV-emitting LED. In one such embodiment, the re-emitting semiconductor construction comprises at least one first potential well not located within a pn junction having a first transition energy corresponding to blue-wavelength light, at least one second potential well not located within a pn junction having a second transition energy corresponding to green-wavelength light, and at least one third potential well not located within a pn junction having a third transition energy corresponding to red-wavelength light.

In some embodiments, the LED is a visible light-emitting LED, typically a green, blue, or violet LED, more typically a green or blue LED, and most typically a blue LED. In one such embodiment, the re-emitting semiconductor construction comprises at least one first potential well not located within a pn junction having a first transition energy corresponding to yellow- or green-wavelength light, more typically green-wavelength light, and at least one second potential well not located within a pn junction having a second transition energy corresponding to orange- or red-wavelength light, more typically red-wavelength light. The re-emitting semiconductor construction may comprise additional potential wells and additional absorbing layers.

In some embodiments, the LED has only one pn junction, and the re-emitting semiconductor construction has only one potential well not located within a pn junction, the potential well having a transition energy corresponding to, for example, green-wavelength light. In such cases the LED emits light at a wavelength shorter than green, e.g., blue, violet, or UV.

The LED and the re-emitting semiconductor construction may be grown using known semiconductor processing techniques in a single fabrication step or process on a single wafer, in which case the LED and re-emitting semiconductor construction preferably utilize the same material combinations, e.g., ZnSe. Alternatively, the LED and the re-emitting semiconductor construction may be grown or fabricated in separate processes and then joined together with a bonding agent or otherwise, and then diced into individual die (either before or after the application of an optical element or array of optical elements corresponding to an array of LEDs formed in an LED wafer). In still other cases, the LED and re-emitting semiconductor construction may be kept separate, for example, bonded or otherwise joined or coupled to different surfaces of an extractor or other optical element.

Any suitable LED may be used. Elements of the disclosed devices, including the LED and the re-emitting semiconductor construction, may be composed of any suitable semiconductors, including Group IV elements such as Si or Ge (other than in light-emitting layers), III-V compounds such as InAs, AlAs, GaAs, InP, AlP, GaP, InSb, AlSb, GaSb, and alloys thereof, II-VI compounds such as ZnSe, CdSe, BeSe, MgSe, ZnTe, CdTe, BeTe, MgTe, ZnS, CdS, BeS, MgS and alloys thereof, or alloys of any of the above. Where appropriate, the semiconductors may be n-doped or p-doped by any suitable method or by inclusion of any suitable dopant. In one typical embodiment, the LED is a III-V semiconductor device and the re-emitting semiconductor construction is a II-VI semiconductor device.

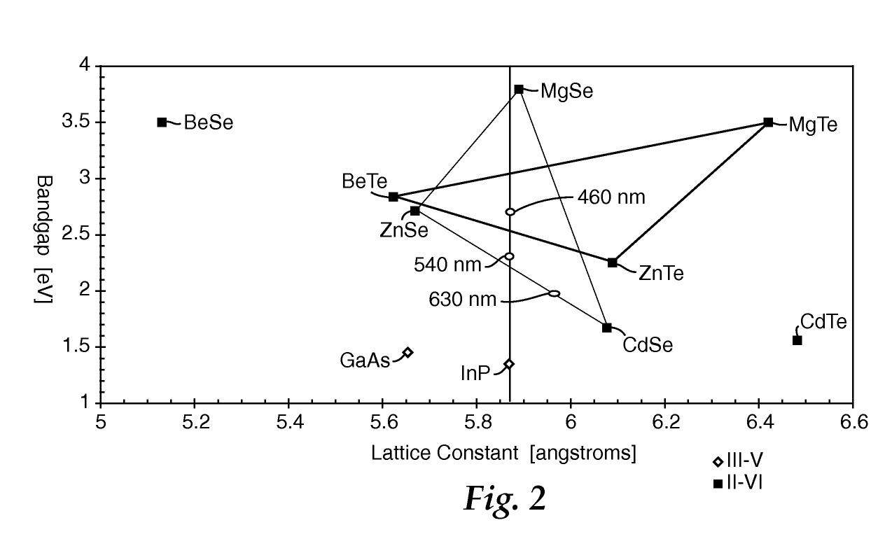

In some embodiments, the compositions of the various layers of a component of the device, such the LED or the re-emitting semiconductor construction, are selected in accordance with the following considerations. Each layer typically will be pseudomorphic to the substrate at the thickness given for that layer or lattice matched to the substrate. Alternately, each layer may be pseudomorphic or lattice matched to immediately adjacent layers. Potential well layer materials and thicknesses are typically chosen so as to provide a desired transition energy, which will correspond to the wavelength of light to be emitted from the quantum well. For example, the points labeled 460 nm, 540 nm and 630 nm in FIG. 2 represent Cd(Mg)ZnSe alloys having lattice constants close to that for an InP substrate (5.8687 Angstroms or 0.58687 nm) and band gap energies corresponding to wavelengths of 460 nm (blue), 540 nm (green) and 630 nm (red). Where a potential well layer is sufficiently thin that quantization raises the transition energy above the bulk band gap energy in the well, the potential well may be regarded as a quantum well. The thickness of each quantum well layer determines the amount of quantization energy in the quantum well, which energy is added to the bulk band gap energy to yield the transition energy in the quantum well. Thus, the wavelength associated with each quantum well can be tuned by adjustment of the quantum well layer thickness. Typically thicknesses for quantum well layers are between 1 nm and 100 nm, more typically between 2 nm and 35 nm. Typically the quantization energy translates into a reduction in wavelength of 20 to 50 nm relative to that expected on the basis of the band gap energy alone. Strain in the emitting layer may also change the transition energy for potential wells and quantum wells, including the strain resulting from the imperfect match of lattice constants between pseudomorphic layers.

Techniques for calculating the transition energy of a strained or unstrained potential well or quantum well are known in the art, e.g., in Herbert Kroemer, Quantum Mechanics for Engineering, Materials Science and Applied Physics (Prentice Hall, Englewood Cliffs, N.J., 1994) at pp. 54-63; and Zory, ed., Quantum Well Lasers (Academic Press, San Diego, Calif., 1993) at pp. 72-79; both incorporated herein by reference.

Any suitable emission wavelengths may be chosen, including those in the infrared, visible, and ultraviolet bands. In some embodiments, the emission wavelengths are chosen so that the combined output of light emitted by the device creates the appearance of any color that can be generated by the combination of two, three, or more monochromatic light sources, including white or near-white colors, pastel colors, magenta, cyan, and the like. In some embodiments, the device emits light at an invisible infrared or ultraviolet wavelength and at a visible wavelength as an indication that the device is in operation. Typically the LED emits photons of the shortest wavelength, so that photons emitted from the LED have sufficient energy to drive the potential wells in the re-emitting semiconductor construction. In one typical embodiment, the LED is a III-V semiconductor device, such as a blue-emitting GaN-based LED, and re-emitting semiconductor construction is a II-VI semiconductor device.

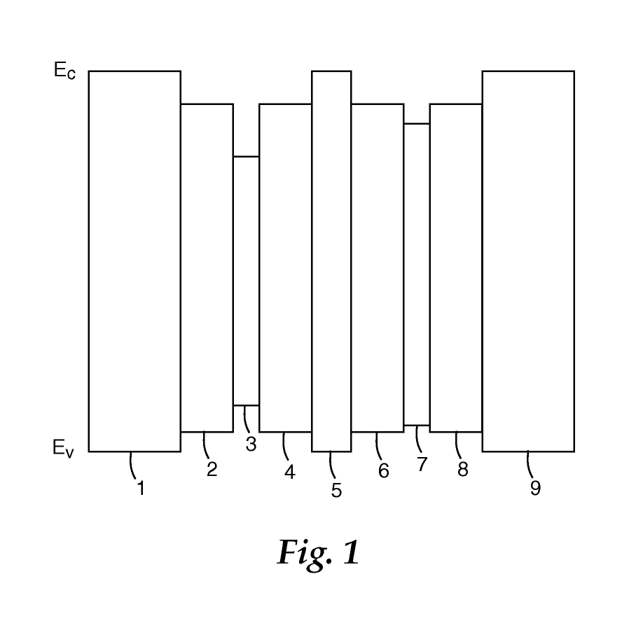

FIG. 1 is a band diagram representing conduction and valence bands of semiconductors in a re-emitting semiconductor construction. Layer thickness is not represented to scale. Table 1 indicates the composition of layers 1-9 in this embodiment and the band gap energy (E_{g}) for that composition. This construction may be grown on an InP substrate.

TABLE I

| Layer | Composition | Band gap Energy (E_{g}) |
|---|---|---|
| 1 | Cd_{0.24}Mg_{0.43}Zn_{0.33}Se | 2.9 eV |
| 2 | Cd_{0.35}Mg_{0.27}Zn_{0.38}Se | 2.6 eV |
| 3 | Cd_{0.70}Zn_{0.30}Se | 1.9 eV |
| 4 | Cd_{0.35}Mg_{0.27}Zn_{0.38}Se | 2.6 eV |
| 5 | Cd_{0.24}Mg_{0.43}Zn_{0.33}Se | 2.9 eV |
| 6 | Cd_{0.35}Mg_{0.27}Zn_{0.38}Se | 2.6 eV |
| 7 | Cd_{0.33}Zn_{0.67}Se | 2.3 eV |
| 8 | Cd_{0.35}Mg_{0.27}Zn_{0.38}Se | 2.6 eV |
| 9 | Cd_{0.24}Mg_{0.43}Zn_{0.33}Se | 2.9 eV |

Layer 3 represents a single potential well which is a red-emitting quantum well having a thickness of about 10 nm. Layer 7 represents a single potential well which is a green-emitting quantum well having a thickness of about 10 nm. Layers 2, 4, 6 and 8 represent absorbing layers, each having a thickness of about 1000 nm. Layers 1, 5 and 9 represent support layers. Support layers are typically chosen so as to be substantially transparent to light emitted from quantum wells 3 and 7 and from a short-wavelength LED. Alternately, the device may comprise multiple red- or green-emitting potential wells or quantum wells separated by absorbing layers and/or support layers.

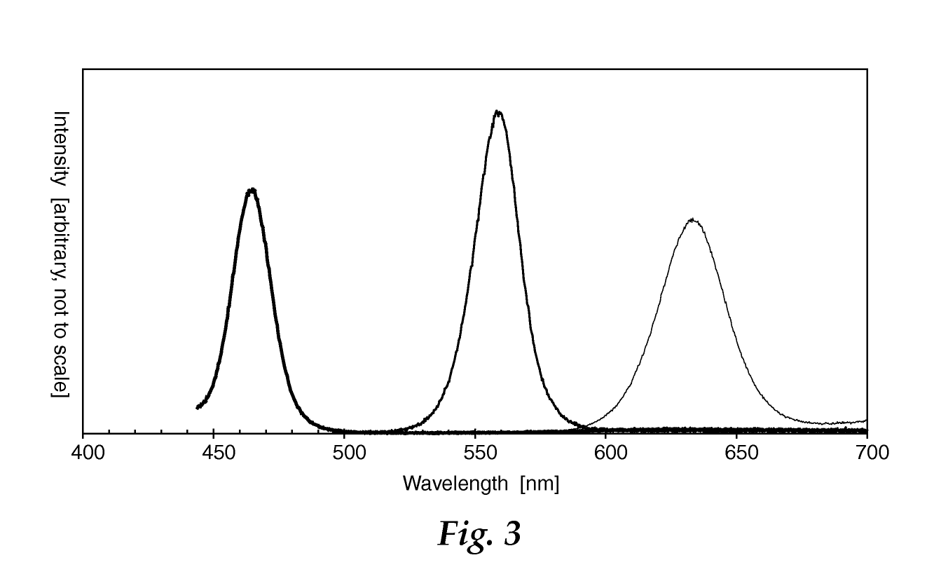

Without wishing to be bound by theory, it is believed that the embodiment represented by FIG. 1 operates according to the following principles: blue wavelength photons emitted by the LED and impinging upon the re-emitting semiconductor construction may be absorbed and re-emitted from the green-emitting quantum well 7 as green-wavelength photons or from the red-emitting quantum well 3 as red-wavelength photons. The absorption of a short-wavelength photon generates an electron-hole pair which may then recombine in the quantum wells, with the emission of a photon. The polychromatic combination of blue-, green-, and red-wavelength light emitted from the device may appear white or near-white in color. The intensity of blue-, green-, and red-wavelength light emitted from the device may be balanced in any suitable manner, including manipulation of the number of quantum wells of each type, the use of filters or reflective layers, and manipulation of the thickness and composition of absorbing layers. FIG. 3 represents a spectrum of light emitted from one embodiment of the device.

Again with reference to the embodiment represented by FIG. 1, absorbing layers 2, 4, 5 and 8 may be adapted to absorb photons emitted from the LED by selecting a band gap energy for the absorbing layers that is intermediate between the energy of photons emitted from the LED and the transition energies of quantum wells 3 and 7. Electron-hole pairs generated by absorption of photons in the absorbing layers 2, 4, 6, and 8 are typically captured by the quantum wells 3 and 7 before recombining with concomitant emission of a photon. Absorbing layers may optionally have a gradient in composition over all or a portion of their thickness, so as to funnel or direct electrons and/or holes toward potential wells. In some embodiments, the LED and the re-emitting semiconductor construction are provided in a single semiconductor unit, i.e., the LED and re-emitting semiconductor construction can be grown in a series of fabrication steps on the same wafer. This semiconductor unit typically contains a first potential well located within a pn junction and a second potential well not located within a pn junction. The potential wells are typically quantum wells. The unit is capable of emitting light at two wavelengths, one corresponding to the transition energy of the first potential well (i.e., light emitted by the LED) and a second corresponding to the transition energy of the second potential well (i.e., light emitted by the re-emitting semiconductor construction). In typical operation, the first potential well emits photons in response to an electric current passing through the pn junction and the second potential well emits photons in response to the absorption of a portion of the photons emitted from the first potential well. The semiconductor unit may additionally comprise one or more absorbing layers surrounding or closely or immediately adjacent to the second potential well. Absorbing layers typically have a band gap energy which is less than or equal to the transition energy of the first potential well and greater than that of the second potential well. In typical operation the absorbing layers assist absorption of photons emitted from the first potential well. The semiconductor unit may comprise additional potential wells, located within the pn junction or located not within the pn junction, and additional absorbing layers.

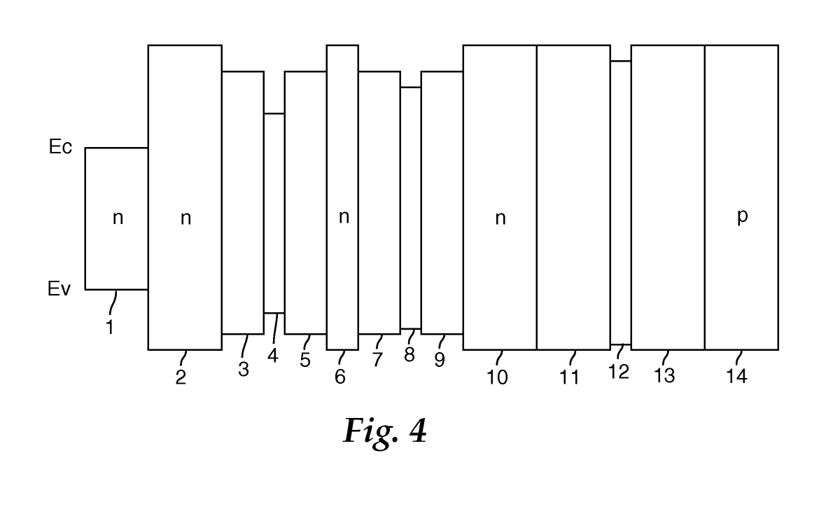

FIG. 4 is a band diagram representing conduction and valence bands of semiconductors in such a semiconductor unit. Layer thickness is not represented to scale. Table II indicates the composition of layers 1-14 in this embodiment and the band gap energy (E_{g}) for that composition.

TABLE II

| Layer | Composition | Band gap Energy (E_{g}) |
|---|---|---|
| 1 | InP substrate | 1.35 eV |
| 2 | n-doped Cd_{0.24}Mg_{0.43}Zn_{0.33}Se | 2.9 eV |
| 3 | Cd_{0.35}Mg_{0.27}Zn_{0.38}Se | 2.6 eV |
| 4 | Cd_{0.70}Zn_{0.30}Se | 1.9 eV |
| 5 | Cd_{0.35}Mg_{0.27}Zn_{0.38}Se | 2.6 eV |
| 6 | n-doped Cd_{0.24}Mg_{0.43}Zn_{0.33}Se | 2.9 eV |
| 7 | Cd_{0.35}Mg_{0.27}Zn_{0.38}Se | 2.6 eV |
| 8 | Cd_{0.33}Zn_{0.67}Se | 2.3 eV |
| 9 | Cd_{0.35}Mg_{0.27}Zn_{0.38}Se | 2.6 eV |
| 10 | n-doped Cd_{0.24}Mg_{0.43}Zn_{0.33}Se | 2.9 eV |
| 11 | undoped Cd_{0.24}Mg_{0.43}Zn_{0.33}Se | 2.9 eV |
| 12 | Cd_{0.31}Mg_{0.32}Zn_{0.37}Se | 2.7 eV |
| 13 | undoped Cd_{0.24}Mg_{0.43}Zn_{0.33}Se | 2.9 eV |
| 14 | p-doped Cd_{0.24}Mg_{0.43}Zn_{0.33}Se | 2.9 eV |

Layers 10, 11, 12, 13 and 14 represent a pn junction, or, more specifically, a pin junction, since intermediate undoped (“intrinsic” doping) layers 11, 12, and 13 are interposed between n-doped layer 10 and p-doped layer 14. Layer 12 represents a single potential well within the pn junction which is a quantum well having a thickness of about 10 nm. Alternately, the device may comprise multiple potential or quantum wells within the pn junction. Layers 4 and 8 represent second and third potential wells not within a pn junction, each being a quantum well having a thickness of about 10 nm. Alternately, the device may comprise additional potential or quantum wells not within the pn junction. In a further alternative, the device may comprise a single potential or quantum well not within the pn junction. Layers 3, 5, 7, and 9 represent absorbing layers, each having a thickness of about 1000 nm. Electrical contacts, not shown, provide a path for supply of electrical current to the pn junction. Electrical contacts conduct electricity and typically are composed of conductive metal. The positive electrical contact is electrically connected, either directly or indirectly through intermediate structures, to layer 14. The negative electrical contact is electrically connected, either directly or indirectly through intermediate structures, to one or more of layers 1, 2, 3, 4, 5, 6, 7, 8, 9, or 10.

Without wishing to be bound by theory, it is believed that this embodiment operates according to the following principles: when an electrical current passes from layer 14 to layer 10, blue-wavelength photons are emitted from quantum well (12) in the pn junction. Photons traveling in the direction of layer 14 may leave the device. Photons traveling in the opposite direction may be absorbed and re-emitted from the second quantum well (8) as green-wavelength photons or from the third quantum well (4) as red-wavelength photons. The absorption of a blue-wavelength photon generates an electron-hole pair which may then recombine in the second or third quantum wells, with the emission of a photon. Green- or red-wavelength photons traveling in the direction of layer 14 may leave the device. The polychromatic combination of blue-, green-, and red-wavelength light emitted from the device may appear white or near-white in color. The intensity of blue-, green- and red-wavelength light emitted from the device may be balanced in any suitable manner, including manipulation of the number of potential wells of each type and the use of filters or reflective layers. FIG. 3 represents a spectrum of light emitted from one embodiment of the device.

Again with reference to FIG. 4, absorbing layers 3, 5, 7, and 9 may be especially suitable to absorb photons emitted from the first quantum well (12), since they have a band gap energy that is intermediate between the transition energy of the first quantum well (12) and those of the second and third quantum wells (8 and 4). Electron-hole pairs generated by absorption of photons in the absorbing layers 3, 5, 7, and 9 are typically captured by the second or third quantum wells 8 and 4 before recombining with concomitant emission of a photon. Absorbing layers may optionally be doped, typically like to surrounding layers, which in this embodiment would be n-doping. Absorbing layers may optionally have a gradient in composition over all or a portion of their thickness, so as to funnel or direct electrons and/or holes toward potential wells.

Where the LED is a visible wavelength LED, the layers of the re-emitting semiconductor construction may be partially transparent to the light emitted from the LED. Alternately, such as where the LED is a UV wavelength LED, one or more of the layers of re-emitting semiconductor construction may block a greater portion or substantially or completely all of the light emitted from the LED, so that a greater portion or substantially or completely all of the light emitted from the device is light re-emitted from the re-emitting semiconductor construction. Where the LED is a UV wavelength LED, the re-emitting semiconductor construction may include red-, green- and blue-emitting quantum wells.

The device may comprise additional layers of conducting, semiconducting, or non-conducting materials. Electrical contact layers may be added to provide a path for supply of electrical current to the LED. The electrical contact layers may be disposed such that the electrical current energizing the LED also passes through the re-emitting semiconductor construction. Alternatively, a portion of the re-emitted semiconductor construction can be etched away to define a hole or aperture through which electrical contact can be made to the p or n layer of the LED. Light filtering layers may be added to alter or correct the balance of light wavelengths in the light emitted by the adapted LED.

In some embodiments, the disclosed light source provides white or near-white light by emitting light at four principal wavelengths in the blue, green, yellow and red bands. In alternative embodiments, the light source generates white or near-white light by emitting light at two principal wavelengths in the blue and yellow bands. In still other embodiments, the light source emits in substantially a single visible color, e.g., green.

The device may comprise additional semiconductor elements comprising active or passive components such as resistors, diodes, zener diodes, capacitors, transistors, bipolar transistors, FET transistors, MOSFET transistors, insulated gate bipolar transistors, phototransistors, photodetectors, SCR's, thyristors, triacs, voltage regulators, and other circuit elements. The device may comprise an integrated circuit. The device may comprise a display panel or an illumination panel.

The LED and the re-emitting semiconductor construction which are included in the disclosed light sources may be manufactured by any suitable method, which may include molecular beam epitaxy (MBE), chemical vapor deposition, liquid phase epitaxy and vapor phase epitaxy. The elements of the device may include any suitable substrate. Typical substrate materials include Si, Ge, GaAs, InP, sapphire, SiC, and ZnSe. The substrate may be n-doped, p-doped, or semi-insulating, which may be achieved by any suitable method or by inclusion of any suitable dopant. Alternately, the elements of the device may be without a substrate. In one embodiment, elements of the device may be formed on a substrate and then separated from the substrate. The elements of the device may also be joined together by any suitable method, including the use of adhesive or welding materials, pressure, heat or combinations thereof. Such methods can be used to bond, for example, the LED (such as an LED die) to the re-emitting semiconductor construction, or the LED to the optical element (such as an extractor), or the re-emitting semiconductor construction to the optical element. Useful semiconductor wafer bonding techniques include those described in chapters 4 and 10 of the text Semiconductor Wafer Bonding by Q.-Y. Tong and U. Gosele (John Wiley & Sons, New York, 1999). Wafer bonding methods described in U.S. Pat. No. 5,915,193 (Tong et al.) and U.S. Pat. No. 6,563,133 (Tong) may also be used. A method for wafer bonding GaN to ZnSe is described in Murai et al., Japanese Journal of Applied Physics 43 No. 10A, page L1275 (2004). In some embodiments a bonding layer is present between the LED and the re-emitting semiconductor construction. The bonding layer may include, for example, a transparent adhesive layer, inorganic thin films, fusable glass frits, or other suitable bonding agents. Additional examples of bonding layers are described in US Pat. Pub. No. 2005/0023545 (Camras et al.). Typically, the bond created is transparent. Bonding methods may include interfacial bonding, or techniques that join the elements (such as the LED and the re-emitting semiconductor construction) only at the edges, i.e., edge bonding. Optionally, refractive index matching layers or interstitial spaces may be included.

LEDs are typically sold in a packaged form that includes an LED die or chip mounted on a metal header. An LED die is an LED in its most basic form, i.e., in the form of an individual component or chip made by semiconductor wafer processing procedures. The component or chip can include electrical contacts suitable for application of power to energize the device. The individual layers and other functional elements of the component or chip are typically formed on the wafer scale, the finished wafer finally being diced into individual piece parts to yield a multiplicity of LED dies. The metal header has a reflective cup in which the LED die is mounted, and electrical leads connected to the LED die. The package further includes a molded transparent resin that encapsulates the LED die. The encapsulating resin typically has a nominally hemispherical front surface to partially collimate light emitted from the LED die. An LED component can be or comprise an LED die or an LED die in combination with a re-emitting semiconductor construction or other elements.

The optical element discussed above can be made separately and then brought into contact or close proximity with a surface of an LED component may be used to couple or “extract” light therefrom and reduce the amount of light trapped within the component. Such an element is referred to as an extractor. Extractors normally have an input surface sized and shaped to substantially mate with a major emitting surface of the LED component.

Extractors can be used to provide high brightness LED packages or light sources. The LED component of such packages may be an LED/ re-emitting semiconductor construction combination, either as separate elements or as a semiconductor unit, as described above or in currently pending U.S. patent applications U.S. Ser. No. 11/009217 or U.S. Ser. No. 11/009241, incorporated herein by reference.

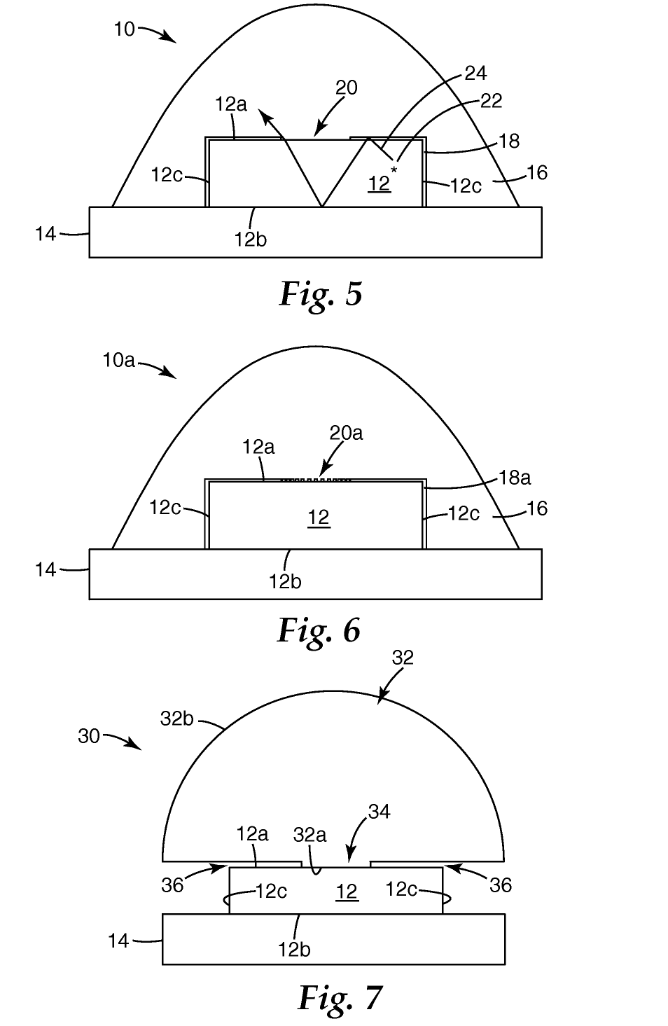

In FIG. 5, an LED package 10 includes an LED component 12 mounted on a header or other mount 14. The LED component and mount are depicted generically for simplicity, but the reader will understand that they can include conventional design features as are known in the art and re-emitting layers as described above. The primary emitting surface 12a, bottom surface 12b, and side surfaces 12c of the LED component are shown in a simple rectangular arrangement, but other known configurations are also contemplated, e.g., angled side surfaces forming an inverted truncated pyramid shape. Electrical contacts to the LED component are also not shown for simplicity, but can be provided on any of the surfaces of the LED component as is known. In exemplary embodiments the LED component has two contacts both disposed at the bottom surface 12b of the LED component, such as is the case with “flip chip” LED component designs. Further, mount 14 can serve as a support substrate, electrical contact, heat sink, and/or reflector cup.

LED package 10 also includes a transparent optical element 16 that encapsulates or surrounds the LED component 12. The optical element 16 has a refractive index intermediate that of the LED component (more precisely, the outer portion of the LED component proximate emitting surface 12a) and the surrounding medium, which is ordinarily air. In many embodiments it is desirable to select a material for element 16 whose refractive index is as high as possible but without substantially exceeding the refractive index of the LED component, since the smaller the difference in refractive index between the LED component and the element 16, the less light is trapped and lost within the LED component. Optical element 16 as shown has a curved output surface, which can help ensure that light is transmitted out of the LED package to the surrounding medium, and can also be used to focus or collimate, at least partially, light emitted by the LED component. Optical elements having other shapes can also be used to collimate light, including tapered shapes discussed further below. Optical element 16 may be an encapsulant, formed in place over the LED component, in which case it is typical for the encapsulant to be or comprise a light transmissive epoxy or silicone.

LED package 10 is further provided with a patterned low refractive index layer 18 between the optical element 16 and the LED component, which has the effect of selectively preserving some light entrapment in the LED component in order to enhance the brightness in a localized aperture or area 20 at the emitting surface 12a. Patterned low index layer 18 is in substantial optical contact with side surfaces 12c and the portion of emitting surface 12a exclusive of aperture 20, while the optical element 16 is in optical contact with the portion of emitting surface 12a over the area of the aperture 20. (In this regard, “optical contact” refers to the surfaces or media being spaced close enough together, including but not limited to being in direct physical contact, that the refractive index properties of the low index layer or transparent element, for example, control or substantially influence total internal reflection of at least some light propagating within the LED component. Typically the surfaces or media are within an evanescent wave of each other, e.g., separated by a gap of 100, 50, or 25 nm or less, including no gap at all.) Patterned low index layer 18 has a refractive index substantially lower than both the refractive index of the LED component and the refractive index of transparent element 16. Layer 18 is also optically thick in those places where it is intended to promote light trapping. By optically thick, we mean that its thickness is great enough to avoid frustrated total internal reflection, or that the refractive index properties of the medium on one side of the layer (such as the optical element 16) do not control or substantially influence total internal reflection of at least some light propagating in the medium on the other side of the layer (such as the LED 12). Preferably, the thickness of the patterned low index layer is greater than about one-tenth, more preferably one-half, more preferably about one wavelength for the energy of light of interest in vacuum. By “patterning” of layer 18 we also mean to encompass embodiments where layer 18 is continuous over the LED emitting surface, but made to be extremely thin (hence ineffective to maintain total internal reflection) in the aperture 20 and optically thick elsewhere. It is advantageous for layer 18 to be a transparent dielectric material, or to at least comprise a layer of such a material at the surface of the LED component. These materials have advantages over reflective coatings made by simply applying a layer of metal to the LED, for example, because dielectric materials can provide 100% reflection (by TIR) for much of the light within the LED component, while simple metal coatings have substantially less than 100% reflectivity, particularly at high incidence angles.

Patterned low index layer 18 enhances the brightness of some portions of the LED (e.g., in the aperture 20) at the expense of reducing the brightness of other portions of the LED (e.g., the portions of emitting surface 12a beyond aperture 20). This effect relies on the LED component having low enough internal losses during operation to support multiple bounce reflections of the emitted light within the LED component. As advances are made in LED component fabrication and design, losses from surface or volumetric absorption can be expected to decrease, internal quantum efficiency can be expected to increase, and brightness-enhancing effect described herein can be expected to provide steadily increasing benefits. Bulk absorption can be reduced by improving substrates and epitaxial deposition processes. Surface absorption can be reduced by improved back reflectors such as by bonding the epitaxial layer to high reflectivity metal mirrors or by incorporating omnidirectional mirrors in the LED structure. Such designs may be more effective when combined with shaping the backside of the LED component to increase light output through the top surface. In exemplary embodiments, the majority of the bottom surface 12b is a highly reflective material such as a metal or a dielectric stack. Preferably the reflector has greater than 90% reflectivity, more preferably 95%, most preferably 99% reflectivity at the LED emission wavelength.

Referring again to FIG. 5, an arbitrary emitting point source 22, for example, emits light ray 24. The refractive indices of LED component 12 and transparent element 16 are such that the ray on its first encounter with the emitting surface 12a at the LED/optical element interface would be transmitted into and refracted by element 16. Patterned layer 18, however, changes the interface at that location to be totally internally reflecting for ray 24. The ray travels through the thickness of the LED component, reflects off the back surface 12b, and again encounters the emitting surface 12a, this time escaping into transparent element 16 because of the absence of layer 18 as shown in FIG. 5. The portion of emitting surface 12a at aperture 20 is thus made brighter (more luminous flux per unit area and per unit solid angle) at the expense of the portion of emitting surface 12a covered by the low index layer 18.

In the embodiment of FIG. 5, some light within the LED that strikes the low index layer 18 can still escape into element 16, if its angle of incidence relative to the emitting surface 12a normal vector is sufficiently small so that it simply passes through low index layer 18. Thus, light striking the low index coated portion of the LED component will have a non-zero but smaller range of escape angles than the uncoated portions. In alternative embodiments, the low index layer 18 can be overcoated with a good normal-incidence reflector such as a reflective metal or an interference reflector to increase recycling of light in the LED component and further enhance the brightness at aperture 20, without losing the benefit of TIR provided by low index layer 18. Optionally, an interference reflector can be positioned between the outer LED component surface and the low index layer 18.

Suitable low index layers 18 include coatings of magnesium fluoride, calcium fluoride, silica, sol gels, fluorocarbons, and silicones. Aerogel materials are also suitable, as they can achieve extremely low effective refractive indices of about 1.2 or less, or even about 1.1 or less. Aerogels are made by high temperature and pressure critical point drying of a gel composed of colloidal silica structural units filled with solvents. The resulting material is an underdense, microporous media. Exemplary thicknesses for the low index layer 18 are from about 50 to 100,000 nm, preferably from about 200 to 2000 nm, depending on the refractive index of the material. The refractive index of layer 18 is below the refractive index of the optical element 16, which can be a molded resin or other encapsulant material, and below the refractive index of the LED component, or that portion of the LED component proximate the emitting surface(s). Preferably the refractive index of layer 18 is less than about 1.5, more preferably less than 1.4. Low index layer 18 can be a solid layer of dielectric material, or a vacuum or gas-filled gap between the LED component and transparent element 16.

The outer surfaces of the LED component can be optically smooth, i.e., having a surface finish RA of less than about 20 nm. Some, all, or portions of the outer LED surfaces may also be optically rough, i.e., having a surface finish RA greater than about 20 nm. Portions of the edges or the top surface can also be at non-orthogonal angles relative to the base of the LED component. These angles can range from 0-45 degrees from orthogonality. Further, major or minor surfaces of the LED component need not be flat. For example, a raised portion or portions of the emitting surface of the LED component can contact a generally flat bottom surface of the optical element to define at least the apertures 20, 20a, and 34 in FIGS. 5-7.

The shape of aperture 20, defined by the substantial absence of the low index layer 18, can be circular, rectangular, square, or more complex shapes, whether polygonal or non-polygonal, regular or irregular. Multiple apertures are also contemplated, as discussed in more detail below. The aperture shape(s) will typically be selected as a function of the intended application, and can be tailored to optimize the overall system performance. It is also contemplated to pattern the surface of the aperture with a continuous or discontinuous pattern or network of low index coated areas, or provide the low index layer with a gradient in thickness or refractive index or both to modify the distribution of light output over the surface of the aperture. The aperture can also cover the entire top emitting surface 12a, where at least portions of the side surfaces 12c are covered with low refractive index layers.

Turning to FIG. 6, an LED package 10a is shown there similar to LED package 10, but where low index layer 18 has been modified by including a network of low index coated areas within the central aperture. The modified low index layer is thus labeled 18a, and the modified central aperture is labeled 20a. Other elements retain the reference numbers used in FIG. 5. As shown, the network of low index areas can be arranged in a pattern that is relatively dense near the edges of the aperture so that transmission is relatively low in that region. The ability to tailor the transmission through the aperture is useful in high brightness LEDs where a specific spatial uniformity or output distribution is required for the system design. Such an arrangement of low refractive index medium within an aperture can likewise be applied to other disclosed embodiments, including without limitation the embodiments of FIGS. 7, 8, and 10-12.

The aperture can be coated with a low index material having a different thickness or different refractive index or both relative to the low index material defining the aperture (referred to as the “surrounding low index material” for convenience). Such design flexibility can be used to modify the angular distribution of light emitted by the packaged LED. For example, coating the aperture 20 or 20a with a material that has a refractive index between that of the optical element 16 and the surrounding low index material will restrict the range of angles of light emitted by the aperture. This will cause light that would ordinarily be emitted at high angles to be recycled within the LED component, and increase the output of light in a range of angles that can be more efficiently used by the associated optical system. For example, collection optics used in electronic projection systems do not efficiently use light that is outside the commonly used F/2 to F/2.5 acceptance design angles.

Turning now to FIG. 7, an LED package 30 includes a transparent optical element 32 in partial optical contact with LED component 12 and partially spaced apart from the LED component to define a substantial air gap 34 therebetween. Transparent element 32 has an input surface 32a and an output surface 32b, the input surface 32a being: smaller than output surface 32b; smaller than emitting surface 12a of the LED component; and in optical contact with a portion of the emitting surface to define aperture 34. In this regard, the input surface is “smaller” than the output surface because it has a smaller surface area, and the output surface is accordingly larger than the input surface because it has a larger surface area. The difference in shape between the optical element 32 and the emitting surface 12a produces an air gap 36 which forms a patterned low refractive index layer around the area of contact (aperture 34). Light generated by the LED component can thus be efficiently extracted at the aperture 34 by the transparent element 32 with a high brightness. The optical element 32, and other optical elements disclosed herein, can be bonded to the LED component at the point of contact by any suitable means, or it can be held in position without being bonded to the LED component emitting surface. Further discussion regarding non-bonded optical elements in LED packages can be found in commonly assigned U.S. Patent Application Publication US 2006/0091784 (Connor et al.), “LED Package With Non-Bonded Optical Element”, which is incorporated herein by reference in its entirety. As discussed above, the range of angles of light emitted by the LED emitting surface 12a into optical element 32 over the aperture 34 can be reduced by interposing a layer of material whose refractive index is between that of the LED component 12 and transparent element 32.

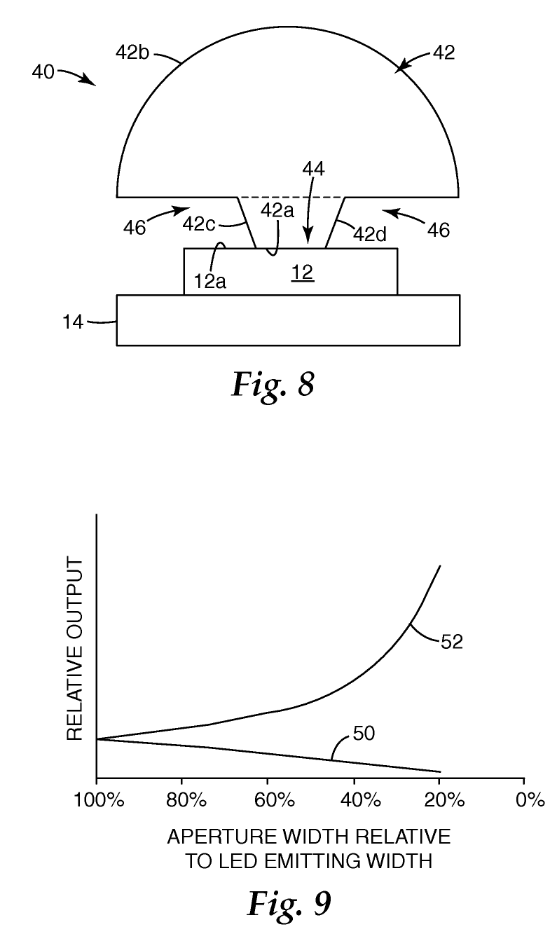

Another approach for reducing the range of angles of collected light—or for collimating (at least partially) the collected light—is to use a transparent element having one or more tapered side walls, as shown in FIG. 8. There, LED package 40 is similar to LED package 30, but optical element 42 is substituted for optical element 32. Element 42 has an input surface 42a and an output surface 42b, the input surface 42a being: smaller than output surface 42b; smaller than emitting surface 12a of the LED component; and in optical contact with a portion of the emitting surface to define aperture 44. The difference in shape between the optical element 42 and the emitting surface 12a produces an air gap 46 which forms a patterned low refractive index layer around the area of contact (aperture 44). Furthermore, optical element 42 includes tapered side surfaces 42c, 42d, which are reflective in order to collimate some of the highly oblique light entering input surface 42a from the LED component. Reflectivity of the side surfaces 42c, 42d can be provided by a low refractive index medium that supports TIR, or by application of a reflective material such as a metal layer or interference reflector, or combinations thereof.

The optical element 42 can be in optical contact with the emitting surface of the LED component through fluids, thermally bound inorganic glasses, plastic inorganic glasses, or by providing the surfaces with an optically smooth finish (surface roughness RA less than about 50 nm, preferably less than about 20 nm) and then holding the surfaces in close proximity to each other. Furthermore, optical element 42 can be compound in structure, where the lower tapered portion comprising surfaces 42a, 42c, 42d is made separately from the upper lens-shaped portion comprising surface 42b, and the two portions adhered or otherwise joined together by conventional means. The broken line is provided to show the two portions more clearly. More discussion of compound optical elements, design considerations, and associated benefits is provided below.

A model was used to determine the potential increase in brightness for a packaged LED that utilized a patterned low index layer and a tapered optical element coupled to the output aperture. An LED die was modeled with the material properties of silicon carbide (index 1.55) having an emitting region, an absorptive region, and angled edge facets such as to represent the optical behavior of a typical LED die. An inverted truncated pyramid-shaped tapered optical element was optically coupled to the front facet or emitting surface of the LED die. The material properties of the optical element were those of silicon carbide. The LED die had a square shape as viewed from the front, as did the input and output surfaces of the optical element. The model further coupled the output surface of the optical element to a half-sphere lens with the material properties of BK7 glass, where the diameter of the lens was ten times the width of the square LED die emitting surface, and the radius of curvature of the lens was five times the width of the LED die emitting surface. The size of the input surface of the optical element, was incrementally changed from 100% of the LED die emitting area to 4%, while keeping the aspect ratio of the height of the optical element 2.2 times the width of the output surface of the optical element, and keeping the width of the output surface 2 times the width of the input surface. As the size of the optical element became less than the size of the LED die emitting surface, a medium of refractive index of 1 was assumed to cover the portion of the LED die emitting surface outside of the optical element input surface, thus forming a low refractive index patterned layer that covered the LED die emitting surface in complementary fashion to the optical element input surface. The fractional power emitted by the optical element (representative of the relative luminous output of the LED package) and the relative irradiance (lumen/(cm²sr) emitted by the output surface of the optical element (representative of the relative brightness of the LED package) was calculated. FIG. 9 depicts in a general way the trend observed. Curve 50 is the relative fractional power emitted; curve 52 is the relative irradiance. The results confirm that as the aperture size decreases, less total luminous output is obtained from the package, but the brightness (in the smaller aperture) can increase dramatically.

Similar results to the model are expected for light source constructions that utilize an LED component, i.e., an LED die in combination with a re-emitting semiconductor construction, e.g., where the re-emitting semiconductor construction is disposed atop the LED die, and the optical element (such as an extractor) is disposed atop the re-emitting semiconductor construction, optically coupled to the emitting surface of the LED component.

The patterned low index layer of disclosed embodiments can comprise a gap or a coating of low index material applied to the LED component. Suitable methods for coating the LED component with a low index material-or with individual layers that will form an interference reflector-from a liquid include spin coating, spray coating, dip coating, and dispensing the coating onto the LED component. Liquid coatings can be composed of monomers that are subsequently cured, solvents, and polymers, inorganic glass forming materials, sol gels, and Aerogels. Suitable methods of coating the low index material from a gas state include chemical vapor deposition or condensing a vapor on the LED component. The LED component can also be coated with a low index material by sputtering, vapor deposition, or other conventional physical vapor deposition methods.

The coatings can be applied to a multitude of LEDs at the wafer level (before dicing), or after the wafer is diced but before mounting, after the LED component is mounted on the header or other support, and after electrical connections are made to the LED component. Coatings can also be applied after bonding a re-emitting semiconductor construction wafer to an LED wafer containing an array of individual LEDs. The aperture can be formed before or after the low index coating is applied. The choice of post-coating patterning method may depend on the particular low index material(s) chosen, and its compatibility with semiconductor processing. For example, a wafer can be covered with photoresist and patterned to create openings where the apertures are desired, a suitable low index coating deposited, and then liftoff performed using suitable solvent. Alternatively, a low index material can be deposited first over the entire wafer or LED component, a patterned photoresist layer can be applied as an etch mask, and the low index material removed using a suitable technique such as reactive ion etching. The photoresist layer can optionally be stripped using a suitable solvent. Other techniques for patterning the low index material include laser ablation and shadow masking, which may be particularly useful with materials that are soluble in typical photolithography stripping or development solvents. Suitable methods for lifting the unwanted coating off of the low adhesion areas include first applying a bonding material and then removing the bonding material, where the bonding material is able to remove the coating from the aperture area but allow the surrounding coating to remain intact. Low index coatings can also be patterned to form areas where electrical connections can be made to the LED component. See, for example, U.S. Patent Publication US 2003/0111667 A1 (Schubert), incorporated herein by reference.

Metal reflective layers can be applied by conventional processes, and patterned as needed to provide an aperture and appropriate electrical isolation.

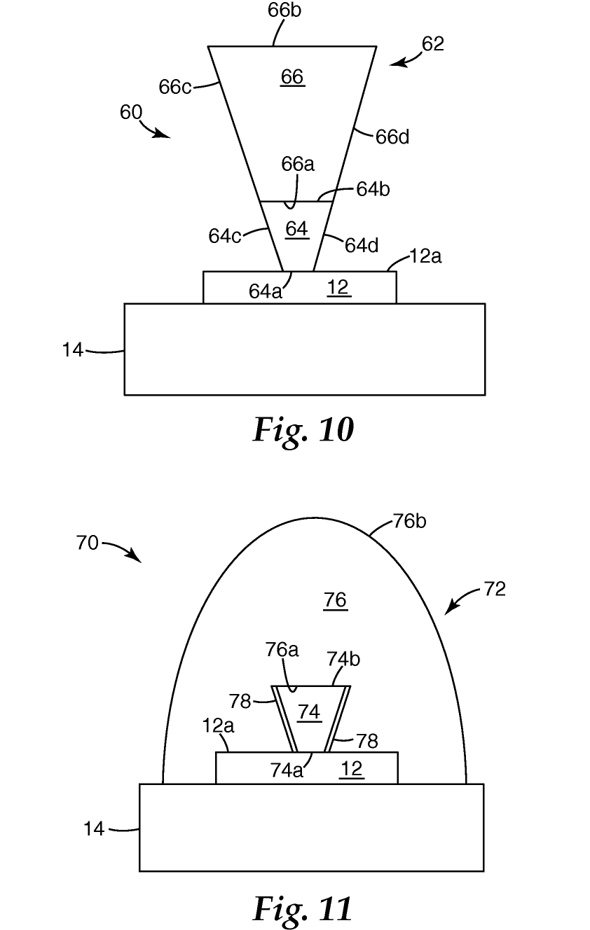

Turning now to FIG. 10, we see there an LED package 60 that utilizes a tapered optical element 62 to couple light out of the LED component 12. As discussed in connection with optical element 42 of FIG. 8, optical element 62 also has a compound construction, i.e., it comprises at least two sections 64, 66 joined together. The sections have input surfaces 64a, 66a, output surfaces 64b, 66b, and reflective side surfaces 64c, 64d, 66c, 66d as shown. The tapered side surfaces of element 62 redirect or collimate (at least partially) light from closely positioned LED emitting surface 12a in a non-imaging way. With tapered element 62 and other tapered elements disclosed herein, the side surfaces need not be planar. They can be conical, curved (including parabolic) or any suitable combination depending on the intended application and design constraints. The disclosed taper elements can have the shape of elements known in the art as CPCs (“compound” parabolic concentrators).

It is desirable in many situations to form the optical tapered element from high refractive index materials to reduce reflections at the LED emitting surface 12a over the aperture defined by input surface 64a, so that light is more efficiently coupled out of, or extracted from, the LED component 12. It is also desirable in many situations to fabricate the optical element using a material having high thermal conductivity and high thermal stability. In this way, the optical element can perform not only an optical function but a thermal management function as well. Further thermal management benefits can be gained by thermally coupling such an optical element to a heat sink, as is described in more detail in commonly assigned U.S. Patent Application Publication 2006/0091414 (Ouderkirk et al.), “LED Package With Front Surface Heat Extractor”, which is incorporated herein by reference in its entirety.

Unfortunately, transparent materials that have sufficiently high refractive indices at the LED emission wavelength, e.g., greater than about 1.8, 2.0, or even 2.5, and/or that have thermal conductivities greater than about 0.2 W/cm/K, tend to be expensive and/or difficult to fabricate. Materials that have both high refractive index and high thermal conductivity include diamond, silicon carbide (SiC), and sapphire (Al₂O₃). These inorganic materials are expensive, physically very hard, and difficult to shape and polish to an optical grade finish. Silicon carbide in particular also exhibits a type of defect called a micropipe, which can result in scattering of light. Silicon carbide is also electrically conductive, and as such may also provide an electrical contact or circuit function. Scattering within optical tapered elements may be acceptable if the scattering is limited to a position near the input end of the element. However, it would be expensive and time consuming to make a tapered element with sufficient length to efficiently couple light from an LED component. An additional challenge in making one-piece tapered elements is that the material yield may be relatively low, and the form-factor may force the LED component to be individually assembled with the tapered element. For these reasons, it can be advantageous to divide the tapered element into at least two sections, the sections being made of different optical materials, to reduce manufacturing cost.

A first section desirably makes optical contact with the LED component, and is made of a first optical material having a high refractive index (preferably about equal to the LED component refractive index at the emitting surface), high thermal conductivity, and/or high thermal stability. In this regard, high thermal stability refers to materials having a decomposition temperature of about 600° C. or more.

A second section is joined to the first section and is made of a second optical material, which may have lower material costs and be more easily fabricated than the first optical material. The second optical material may have a lower refractive index, lower thermal conductivity, or both relative to the first optical material. For example, the second optical material can comprise glasses, polymers, ceramics, ceramic nanoparticle-filled polymers, and other optically clear materials. Suitable glasses include those comprising oxides of lead, zirconium, titanium, and barium. The glasses can be made from compounds including titanates, zirconates, and stannates. Suitable ceramic nanoparticles include zirconia, titania, zinc oxide, and zinc sulfide.

A third section composed of a third optical material can be joined to the second section to further aid in coupling the LED light to the outside environment. In one embodiment the refractive indices of the three sections are arranged such that n₁>n₂>n₃ to minimize overall Fresnel surface reflections associated with the tapered element.

Oversized lens elements, such as the upper portion of optical element 42 shown in FIG. 8, can be advantageously placed or formed at the output end of disclosed simple or compound tapered elements. Antireflection coatings can also be provided on the surface(s) of such lens elements and/or on input and output surfaces of disclosed optical elements, including tapered or other collimating elements.

In an exemplary arrangement, the LED die can comprise a 1 mm×1 mm GaN junction on a 0.4 mm thick slab of SiC. The first section 64 of the tapered element 62 can be composed of SiC. The second section 66 can be composed of LASF35, a non-absorbing, non-scattering high index glass having n=2.0. The width dimensions of the junction between the first and second sections and the output dimensions of the second section can be selected as desired to optimize total light output into the surrounding environment, of refractive index 1.0. The edges of the 0.4 mm thick SiC slab can be tapered at a 12 degree negative slope to completely frustrate TIR modes of light reflection at the side surfaces of the LED component. This slope can be tailored as desired, since the absorption and scattering within the LED junction and SiC slab will change the integrated mode structure compared to a standard encapsulated LED. For example, it may be desirable to use a positive slope (where the width of the LED junction is less than the width of the SiC slab) in order to direct optical modes away from the absorbing junction. The SiC slab may, in this manner, be considered as part of the tapered element.

The first section 64 can be coupled to a thermal heat sink as mentioned previously. The second section 66 can be bonded to the first section 64 using conventional bonding techniques. If a bonding material is used, it can have a refractive index between the two optical materials being joined in order to reduce Fresnel reflections. Other useful bonding techniques include wafer bonding techniques known in the semiconductor wafer bonding art. Useful semiconductor wafer bonding techniques include those discussed above.

The LED package 70 shown in FIG. 11 utilizes a compound tapered element 72 in which a first section 74, having an input surface 74a connected to a larger output surface 74b by tapered reflective side walls, is encapsulated in a second section 76, which also has an input surface 76a (coextensive with output surface 74b) and an even larger output surface 76b. The output surface 76a is curved to provide the compound element 72 with optical power useful for further collimation or focusing. The tapered side surfaces of section 74 are shown with a coating 78 of low refractive index material to promote TIR at such surfaces. The material preferably has a refractive index lower than that of first section 74, second section 76, and LED component 12. Such coating 78 can also be applied to the portion of emitting surface 12a not in contact with section 74, and/or to the side surfaces 12c (see FIG. 5) of LED component 12. In constructing LED package 70, first section 74 can be bonded to (or simply placed upon) the desired aperture zone of emitting surface 12a, and a precursor liquid encapsulating material can be metered out in sufficient quantity to encapsulate the LED component and the first section, followed by curing the precursor material to form the finished second section 76. Suitable materials for this purpose include conventional encapsulation formulations such as silicone or epoxy materials. The package can also include a heat sink coupled to the sides of first section 76 through coating 78. Even without such a heat sink, use of a high thermal conductivity first section of the tapered element can add significant thermal mass to the LED component, providing some benefit at least for pulsed operation using a modulating drive current.

Both simple tapered elements and compound tapered elements disclosed herein can be manufactured by conventional means, such as by fabricating the tapered components individually, bonding a first segment to the LED component, and then adding successive segments. Alternatively, simple and compound tapered elements can be manufactured using precision abrasive techniques disclosed in commonly assigned U.S. Patent Application Publication 2006/0094340 (Ouderkirk et al.), “Process For Manufacturing Optical And Semiconductor Elements”, and U.S. Patent Application Publication 2006/0094322 (Ouderkirk et al.), “Process For Manufacturing A Light Emitting Array”, both of which are incorporated herein by reference in their entirety. Briefly, a workpiece is prepared that contains one or more layers of the desired optical materials. The workpiece can be in a large format, such as wafers or fiber segments. A precisely patterned abrasive is then brought into contact with the workpiece so as to abrade channels in the workpiece. When abrasion is complete, the channels define a multiplicity of protrusions, which can be in the form of simple or compound tapered elements. The tapered elements can be removed individually from the workpiece and bonded one-at-a-time to separate LED components, or an array of tapered elements can conveniently be bonded to an array of LED components.

Furthermore, optical elements such as extractors can be made using the techniques described in commonly assigned U.S. patent application Ser. No. 11/381,512 (Attorney Docket No. 62114US002), filed May 3, 2006, and can be made using the high refractive index materials disclosed in commonly assigned U.S. patent application Ser. No. 11/381,518 (Attorney Docket 61216US002), filed May 3, 2006, both of which pending applications are incorporated herein by reference.

When optical coupling elements whose input surfaces are smaller than the emitting surface of the LED component are used, it becomes possible to consider coupling multiple such elements to different portions of the same emitting surface.

Advantageously, such an approach can be used to reduce the quantity of optical material necessary to couple a given amount of light out of the LED component, by simply replacing a single optical taper element with a plurality of smaller ones. The difference in material usage can be particularly important when dealing with expensive and difficult-to-work-with materials such as diamond, SiC, and sapphire. For example, replacing a single optical tapered element with a 2×2 array of smaller optical tapered elements can reduce the required thickness for the high index (first) optical material by a factor of more than 2, and a 3×3 array can reduce the required thickness by a factor of more than 3. Surprisingly, even though light may not be efficiently emitted from the LED in places between the input surfaces of the optical elements, modeling shows that this approach still has a very high net extraction efficiency.

Another advantage of using multiple optical coupling elements such as tapered elements is that gaps or spaces are formed between the elements that can be utilized for various purposes. For example, the gaps or spaces can be filled with high refractive index fluids, metal heat conductors, electrical conductors, thermal transport fluids, and combinations thereof.

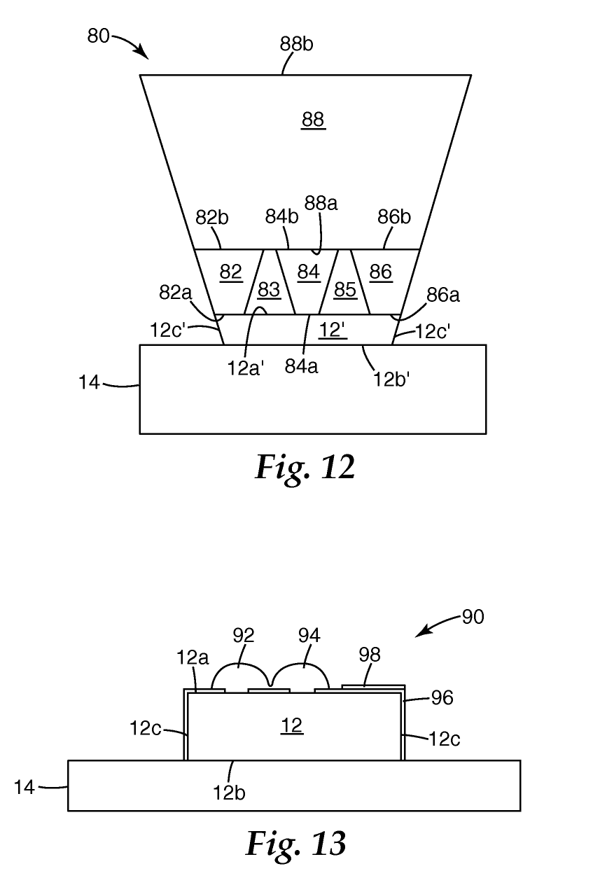

Modeling was performed on an LED package in which the LED die was constructed of SiC and an absorbing layer adjusted such that 30% of the light generated within the LED die was emitted from the LED when immersed in a 1.52 refractive index medium. This is representative of typical LED devices. The model used a 3×3 array of optical tapered elements coupled to the LED emitting surface as shown in the LED package 80 of FIG. 12. The LED die 12′ shown there has angled side surfaces 12c′ and front emitting surface 12a′, to which three of the optical tapered elements 82, 84, 86 are shown coupled at their input surfaces 82a, 84a, 86a respectively. Note the spaces or gaps 83, 85 formed between the smaller optical elements. The output surfaces 82b, 84b, 86b couple to an input surface 88a of larger optical tapered element 88, which has output surface 88b. The model also used a hemispherical lens (not shown) that was oversized relative to taper element 88, with its flat surface attached to output surface 88b, the lens being made of BK7 glass (n=1.52). The tapered element 88 was modeled as being composed of LAS35 (n=about 2). The model then evaluated different optical materials for the smaller taper elements, and different materials for the ambient space surrounding the LED component, including gaps 83, 85.

The calculated output power (e.g. in Watts) of the modeled LED package is as follows as a function of the small tapered element optical material (designated “A” in the table) and the ambient material (designated “B” in Table III):

TABLE III

| | | Optical material for “B” | | | |
|---|---|---|---|---|---|
| | | SiC | LASF35 | BK7 | Vacuum |
| Optical | SiC | 0.821 | 0.814 | 0.775 | 0.754 |
| material for | LASF35 | 0.826 | 0.771 | 0.701 | 0.665 |
| “A” | BK7 | 0.625 | 0.613 | 0.537 | 0.466 |

When these values are normalized to the power output of a system using a single SiC tapered element in place of the 3×3 array of smaller elements, the following results are obtained (Table IV):

TABLE IV

| | | Optical material for “B” | | | |
|---|---|---|---|---|---|
| | | SiC | LASF35 | BK7 | Vacuum |
| Optical | SiC | 100% | 99% | 94% | 92% |
| material for | LASF35 | 101% | 94% | 85% | 81% |
| “A” | BK7 | 76% | 76% | 65% | 57% |

Tables III and IV show that an optical tapered element does not have to be optically coupled over the full area of the LED emitting surface to efficiently extract light. The tables also show that the ambient volume between the small taper elements can have a low refractive index without causing a substantial reduction in extraction efficiency. Similar results are expected for light sources utilizing an LED component that comprises both an LED and a re-emitting semiconductor construction.

The ambient volume can be filled with a material to increase extraction efficiency. The filler material can be a fluid, an organic or inorganic polymer, an inorganic particle-filled polymer, a salt, or a glass. Suitable inorganic particles include zirconia, titania, and zinc sulfide. Suitable organic fluids include any that are stable at the LED operating temperature and to the light generated by the LED. In some cases, the fluid should also have a low electrical conductivity and ion concentration. Suitable fluids include water, halogenated hydrocarbons, and aromatic and heterocyclic hydrocarbons. The filler material can also serve to bond the optical tapered elements to the LED component.

At least a portion of the space between the optical elements can have metal applied to either distribute current to the LED component, or to remove heat from the LED component, or both. Since metals have measurable absorption of light, it can be desirable to minimize absorptive losses. This can be done by minimizing the contact area of the metal with the LED component, and reducing the optical coupling to the metal by introducing a low refractive index material between the metal and the LED component surface, the optical element, or both. For example, the contact area can be patterned with an array of metal contacts surrounded by low index material which are in electrical conduct with an upper metal layer. See e.g. the '667 Schubert publication referenced above. Suitable low index materials include a gas or vacuum, fluorocarbons such as fluorinert, available from 3M Company, St. Paul, Minn., water, and hydrocarbons. The metal can extend into a media surrounding the optical element where heat can be removed.

Fluids can also be provided between the tapered elements to remove additional heat. The array of optical tapered elements can be in a square array (e.g. 2×2, 3×3, etc.), a rectangular array (e.g. 2×3, 2×4, etc.), or a hexagonal array. The individual optical tapered elements can be square, rectangular, triangular, circular, or other desired shape in cross-section at their input or output surfaces. The array can extend over the entire emitting surface of the LED, or beyond, or only over a portion thereof. The tapered elements can be attached to the LED emitting surface with a low softening temperature solder glass, a soft inorganic coating such as zinc sulfide, a high index fluid, a polymer, a ceramic filled polymer, or by providing the optical elements and LED with very smooth and flat surfaces, and mechanically holding the LED component against the input surfaces of the optical elements.

Another LED package 90 having multiple optical elements 92, 94 and a patterned low index layer 96 is depicted in FIG. 13. The patterned low index layer 96 includes two apertures as shown over which optical elements 92, 94 are disposed in optical contact with emitting surface 12a of the LED component. Layer 96 is also in optical contact with LED component emitting surface 12a, as well as with LED component side surfaces 12c. LED package 90 further includes a metal contact 98 shown atop a portion of low index layer 96. Although not shown in FIG. 13, patterned layer 96 is also patterned in the vicinity of metal contact 98, and metal contact 98 desirably extends through holes in the layer 96 to provide electrical contact to LED component 12. A second electrical contact can be provided at another location on the LED component depending on the chip design.

Extractors and other optical elements useful in the disclosed light sources can have a wide variety of shapes, sizes, and configurations. Converging optical elements, for example, have also found to be useful in efficiently extracting light out of LED components and modifying the angular distribution of the emitted light. The LED component of such packages may be an LED/ re-emitting semiconductor construction combination, either as separate elements or as a semiconductor unit, as described above or in currently pending U.S. patent applications U.S. Ser. No. 11/009217 or U.S. Ser. No. 11/009241, incorporated herein by reference.

The optical elements can efficiently extract light out of LED components, and modify the angular distribution of the emitted light. Each optical element is optically coupled to the emitting surface an LED component (or LED component array) to efficiently extract light and to modify the emission pattern of the emitted light. LED sources that include optical elements can be useful in a variety of applications, including, for example, backlights in liquid crystal displays or backlit signs.

Light sources comprising converging optical elements described herein can be suited for use in backlights, both edge-lit and direct-lit constructions. Wedge-shaped optical elements are particularly suited for edge-lit backlights, where the light source is disposed along an outer portion of the backlight. Pyramid or cone-shaped converging optical elements can be particularly suited for use in direct-lit backlights. Such light sources can be used as single light source elements, or can be arranged in an array, depending on the particular backlight design.

For a direct-lit backlight, the light sources are generally disposed between a diffuse or specular reflector and an upper film stack that can include prism films, diffusers, and reflective polarizers. These can be used to direct the light emitted from the light source towards the viewer with the most useful range of viewing angles and with uniform brightness. Exemplary prism films include brightness enhancement films such as BEF™ available from 3M Company, St. Paul, Minn. Exemplary reflective polarizers include DBEF™ also available from 3M Company, St. Paul, Minn. For an edge-lit backlight, the light source can be positioned to inject light into a hollow or solid light guide. The light guide generally has a reflector below it and an upper film stack as described above.

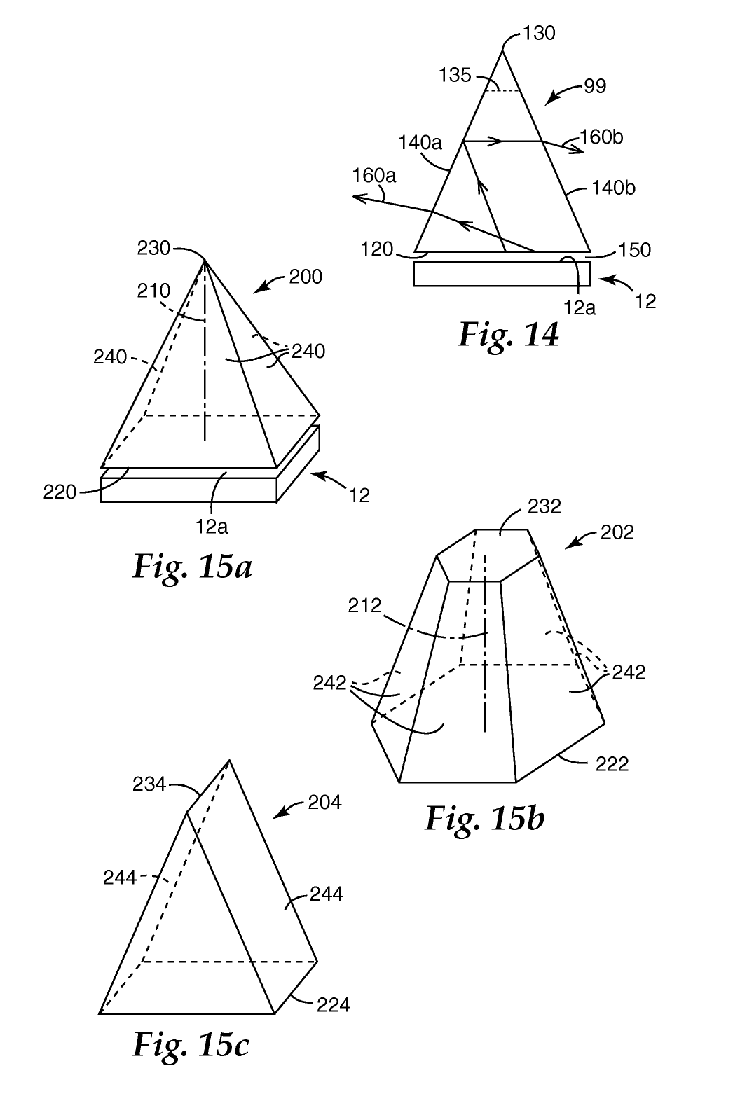

FIG. 14 is a schematic side view illustrating a light source according to one embodiment. The light source comprises an optical element 99 and LED component 12. The optical element 99 has a triangular cross-section with a base 120 and two converging sides 140 joined opposite the base 120 to form an apex 130. The apex can be a point, as shown at 130 in FIG. 14, or can be blunted, as for example in a truncated triangle (shown by dotted line 135). A blunted apex can be flat, rounded, or a combination thereof The apex is smaller than the base and preferably resides over the base. In some embodiments, the apex is no more than 20% of the size of the base. Preferably, the apex is no more than 10% of the size of the base. In FIG. 14, the apex 130 is centered over the base 120. However, embodiments where the apex is not centered or is skewed away from the center of the base are also contemplated.

The optical element 99 is optically coupled to (or in optical contact with) the LED component 12 to extract light emitted by the LED component 12. The primary emitting surface 12a of the LED component 12 is substantially parallel and in close proximity to the base 120 of the optical element 99. The LED component 12 and optical element 99 can be optically coupled in a number of ways including bonded and non-bonded configurations, which are described in more detail below.

The converging sides 140a-b of the optical element 99 act to modify the emission pattern of light emitted by the LED component 12, as shown by the arrows 160a-b in FIG. 14. A typical bare LED component emits light in a first emission pattern. Typically, the first emission pattern is generally forward emitting or has a substantial forward emitting component. A converging optical element, such as optical element 99 depicted in FIG. 14, modifies the first emission pattern into a second, different emission pattern. For example, a wedge-shaped optical element directs light emitted by the LED component to produce a side-emitting pattern having two lobes. FIG. 14 shows exemplary light rays 160a-b emitted by the LED component entering the optical element 99 at the base. A light ray emitted in a direction forming a relatively low incidence angle with the converging side 140a will be refracted as it exits the high index material of the optical element 20 into the surrounding medium (e.g. air). Exemplary light ray 160a shows one such light ray, incident at a small angle with respect to normal. A different light ray, emitted at a high incidence angle, an angle greater than or equal to the critical angle, will be totally internally reflected at the first converging side it encounters (140a). However, in a converging optical element such as the one illustrated in FIG. 14, the reflected ray will subsequently encounter the second converging side (140b) at a low incidence angle, where it will be refracted and allowed to exit the optical element. An exemplary light ray 160b illustrates one such light path.

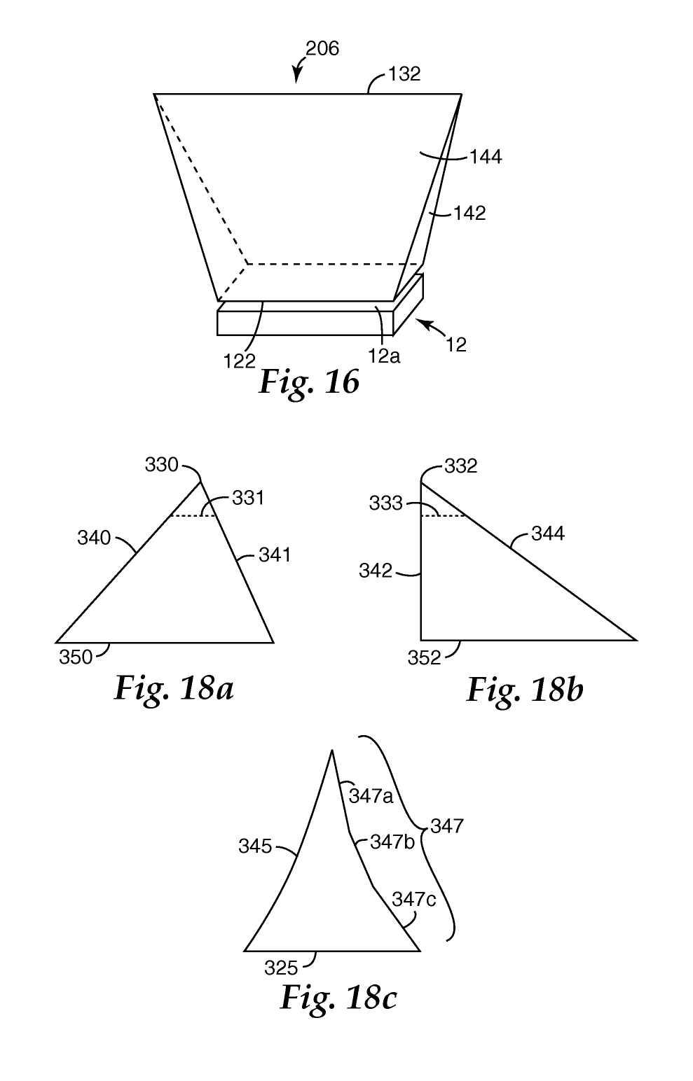

An optical element having at least one converging side can modify a first light emission pattern into a second, different light emission pattern. For example, a generally forward emitting light pattern can be modified into a second, generally side-emitting light pattern with such a converging optical element. In other words, a high index optical element can be shaped to direct light emitted by the LED component to produce a side emitting pattern. If the optical element is rotationally symmetric (e.g. shaped as a cone) the resulting light emission pattern will have a torroidal distribution—the intensity of the emitted light will be concentrated in a circular pattern around the optical element. If, for example, an optical element is shaped as a wedge (e.g. see FIG. 16) the side emitting pattern will have two lobes—the light intensity will be concentrated in two zones. In case of a symmetric wedge, the two lobes will be located on opposing sides of the optical element (two opposing zones). For optical elements having a plurality of converging sides, the side emitting pattern will have a corresponding plurality of lobes. For example, for an optical element shaped as a four-sided pyramid, the resulting side emitting pattern will have four lobes. The side emitting pattern can be symmetric or asymmetric. An asymmetric pattern will be produced when the apex of the optical element is placed asymmetrically with respect to the base or emission surface. Those skilled in the art will appreciate the various permutations of such arrangements and shapes to produce a variety of different emission patterns, as desired.

In some embodiments, the side emitting pattern has an intensity distribution with a maximum at a polar angle of at least 30°, as measured in an intensity line plot. In other embodiments the side emitting pattern has an intensity distribution centered at a polar angle of at least 30°. Other intensity distributions are also possible with presently disclosed optical elements, including, for example those having maxima and/or centered at 45° and 60° polar angle.

Converging optical elements can have a variety of forms. Each optical element has a base, an apex, and at least one converging side. The base can have any shape (e.g. square, circular, symmetrical or non-symmetrical, regular or irregular). The apex can be a point, a line, or a surface (in case of a blunted apex). Regardless of the particular converging shape, the apex is smaller in surface area than the base, so that the side(s) converge from the base towards the apex. A converging optical element can be shaped as a pyramid, a cone, a wedge, or a combination thereof. Each of these shapes can also be truncated near the apex, forming a blunted apex. A converging optical element can have a polyhedral shape, with a polygonal base and at least two converging sides. For example, a pyramid or wedge-shaped optical element can have a rectangular or square base and four sides wherein at least two of the sides are converging sides. The other sides can be parallel sides, or alternatively can be diverging or converging. The shape of the base need not be symmetrical and can be shaped, for example, as a trapezoid, parallelogram, quadrilateral, or other polygon. In other embodiments, a converging optical element can have a circular, elliptical, or an irregularly-shaped but continuous base. In these embodiments, the optical element can be said to have a single converging side. For example, an optical element having a circular base can be shaped as a cone. Generally, a converging optical element comprises a base, an apex residing (at least partially) over the base, and one or more converging sides joining the apex and the base to complete the solid.

FIG. 15a shows one embodiment of a converging optical element 200 shaped as a four-sided pyramid having a base 220, an apex 230, and four sides 240. In this particular embodiment, the base 220 can be rectangular or square and the apex 230 is centered over the base (a projection of the apex in a line 210 perpendicular to the plane of the base is centered over the base 220). FIG. 15a also shows LED component 12 having emitting surface 12a which is proximate and parallel to the base 220 of the optical element 200. The LED component 12 and optical element 200 are optically coupled at the emitting surface—base interface. Optical coupling can be achieved in several ways, described in more detail below. For example, the LED component and optical element can be bonded together. In FIG. 15a the base and the emitting surface of the LED component are shown as substantially matched in size. In other embodiments, the base can be larger or smaller than the LED component emitting surface.

FIG. 15b shows another embodiment of a converging optical element 202. Here, optical element 202 has a hexagonal base 222, a blunted apex 232, and six sides 242. The sides extend between the base and the apex and each side converges towards the apex 232. The apex 232 is blunted and forms a surface also shaped as a hexagon, but smaller than the hexagonal base.

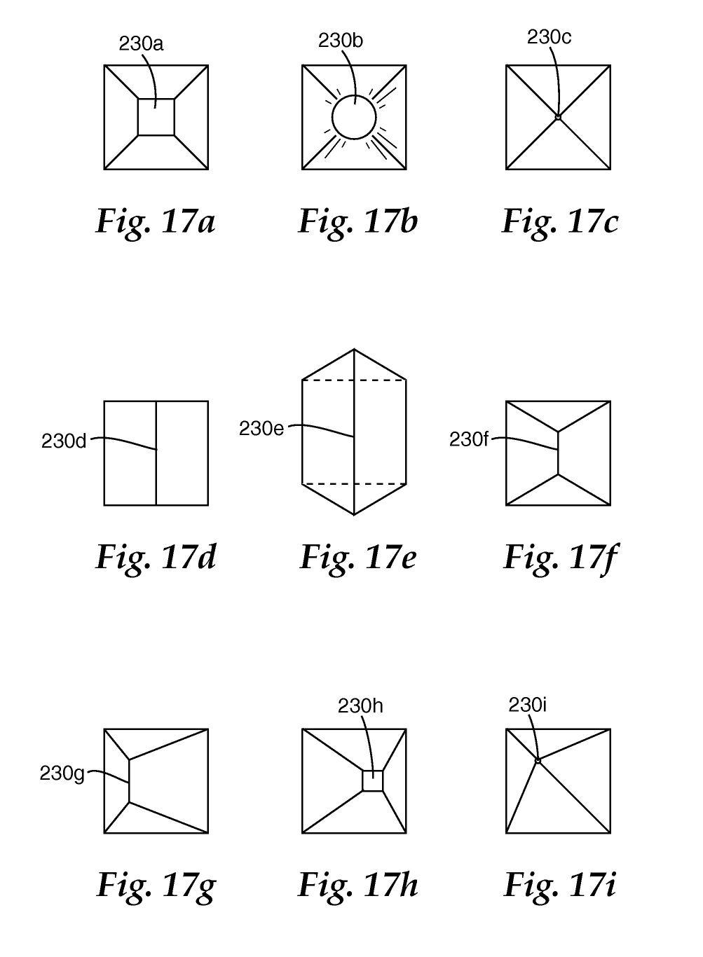

FIG. 15c shows another embodiment of an optical element 204 having two converging sides 244, a base 224, and an apex 234. In FIG. 15c, the optical element is shaped as a wedge and the apex 234 forms a line. The other two sides are shown as parallel sides. Viewed from the top, the optical element 204 is depicted in FIG. 17d.

Alternative embodiments of wedge-shaped optical elements also include shapes having a combination of converging and diverging sides, such as the optical element 206 shown in FIG. 16. In the embodiment of FIG. 16, the wedge-shaped optical element 206 resembles an axe-head. The two diverging sides 142 act to collimate the light emitted by the LED component. The two converging sides 144 converge at the top forming an apex 132 shaped as a line residing over the base when viewed from the side (see FIG. 14), but having portions extending beyond the base when viewed as shown in FIG. 16 (or FIG. 17e). The converging sides 144 allow the light emitted by the LED component 12 to be redirected to the sides, as shown in FIG. 14. Other embodiments include wedge shapes where all sides converge, for example as shown in FIG. 17f.

The optical element can also be shaped as a cone having a circular or elliptical base, an apex residing (at least partially) over the base, and a single converging side joining the base and the apex. As in the pyramid and wedge shapes described above, the apex can be a point, a line (straight or curved) or it can be blunted forming a surface.

FIGS. 17a-i show top views of several alternative embodiments of an optical element. FIGS. 17a-f show embodiments in which the apex is centered over the base. FIGS. 17g-i show embodiments of asymmetrical optical elements in which the apex is skewed or tilted and is not centered over the base.

FIG. 17a shows a pyramid-shaped optical element having a square base, four sides, and a blunted apex 230a centered over the base. FIG. 17h shows a pyramid-shaped optical element having a square base, four sides, and a blunted apex 230h that is off-center. FIG. 17b shows an embodiment of an optical element having a square base and a blunted apex 230b shaped as a circle. In this case, the converging sides are curved such that the square base is joined with the circular apex. FIG. 17c shows a pyramid-shaped optical element having a square base, four triangular sides converging at a point to form an apex 230c, which is centered over the base. FIG. 17i shows a pyramid-shaped optical element having a square base, four triangular sides converging at a point to form an apex 230i, which is skewed (not centered) over the base.

FIGS. 17d-g show wedge-shaped optical elements. In FIG. 17d, the apex 230d forms a line residing and centered over the base. In FIG. 17e, the apex 230e forms a line that is centered over the base and partially resides over the base. The apex 230e also has portions extending beyond the base. The top view depicted in FIG. 17e can be a top view of the optical element shown perspective in FIG. 16 and described above. FIGS. 17f and 17g show two alternative embodiments of a wedge-shaped optical element having an apex forming a line and four converging sides. In FIG. 17f, the apex 230f is centered over the base, while in FIG. 17g, the apex 230g is skewed.

FIGS. 18a-c show side views of an optical element according to alternative embodiments. FIG. 18a shows one embodiment of an optical element having a base 350 and sides 340 and 341 starting at the base 350 and converging towards an apex 330 residing over the base 350. Optionally, the sides can converge toward a blunted apex 331. FIG. 18b shows another embodiment of an optical element having a base 352, a converging side 344 and a side 342 perpendicular to the base. The two sides 342 and 344 form an apex 332 residing over the edge of the base. Optionally, the apex can be a blunted apex 333. FIG. 18c shows a side view of an alternative optical element having a generally triangular cross section. Here, the base 325 and the sides 345 and 347 generally form a triangle, but the sides 345 and 347 are non-planar surfaces. In FIG. 18c the optical element has a left side 345 that is curved and a right side that is faceted (i.e. it is a combination of three smaller flat portions 347a-c). The sides can be curved, segmented, faceted, convex, concave, or a combination thereof. Such forms of the sides still function to modify the angular emission of the light extracted similarly to the planar or flat sides described above, but offer an added degree of customization of the final light emission pattern.

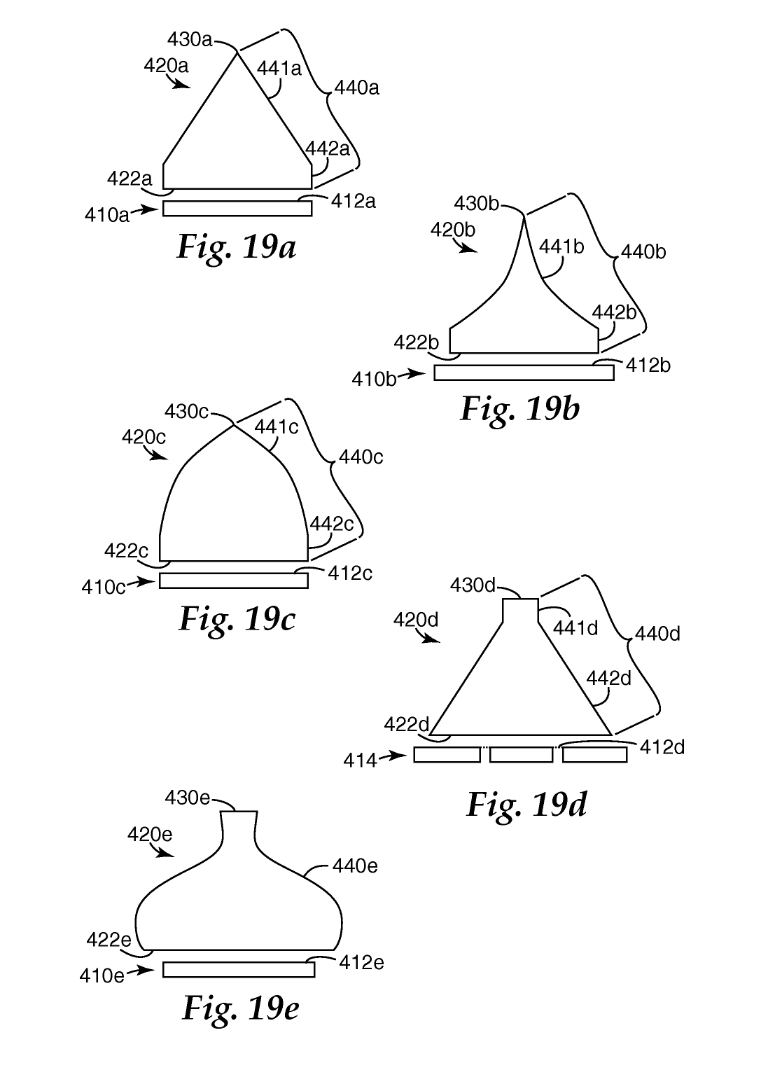

FIGS. 19a-e depict alternative embodiments of optical elements 420a-e having non-planar sides 440a-e extending between each base 422a-e and apex 430a-e, respectively. In FIG. 19a, the optical element 420a has sides 440a comprising two faceted portions 441a and 442a. The portion 442a near the base 422a is perpendicular to the base 422a while the portion 441a converges toward the apex 430a. Similarly, in FIGS. 19b-c, the optical elements 420b-c have sides 440b-c formed by joining two portions 441b-c and 442b-c, respectively. In FIG. 19b, the converging portion 441b is concave. In FIG. 19c, the converging portion 441c is convex. FIG. 19d shows an optical element 420d having two sides 440d formed by joining portions 441d and 442d. Here, the portion 442d near the base 422d converges toward the blunted apex 430d and the top-most portion 441d is perpendicular to the surface of the blunted apex 630d. FIG. 19e shows an alternative embodiment of an optical element 420e having curved sides 440e. Here, the sides 440e are s-shaped, but generally converge towards the blunted apex 430e. When the sides are formed of two or more portions, as in FIGS. 19a-e, preferably the portions are arranged so that the side is still generally converging, even though it may have portions which are non-converging.

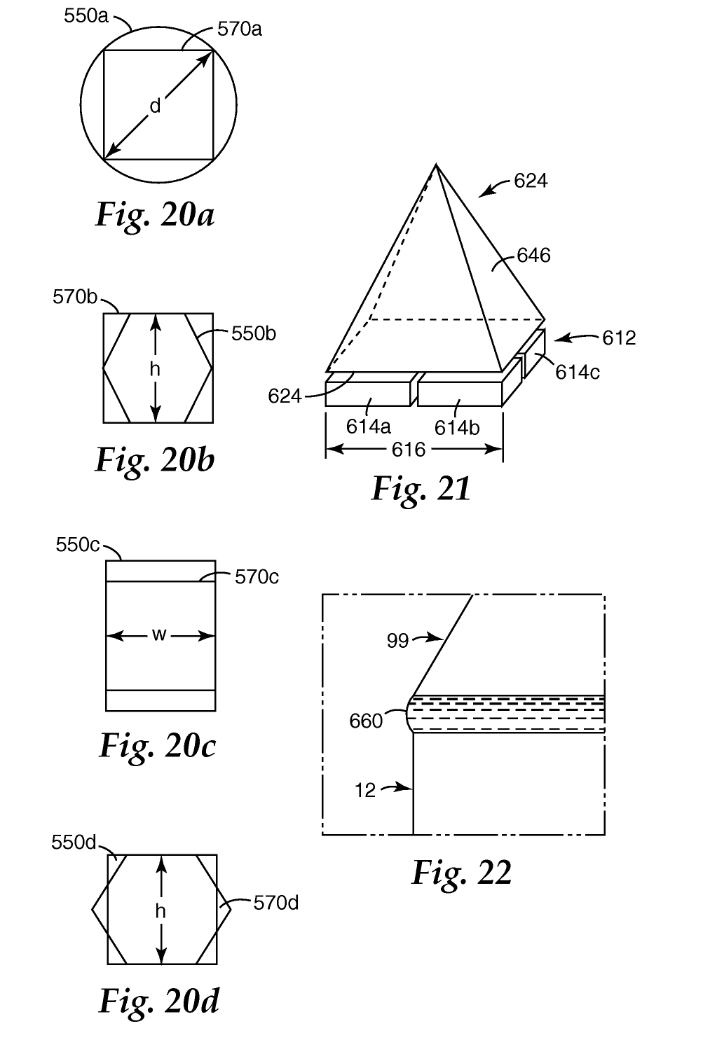

Preferably, the size of the base is matched to the size of the LED component at the emitting surface. FIGS. 20a-d show exemplary embodiments of such arrangements. In FIG. 20a an optical element having a circular base 550a is optically coupled to an LED component having a square emitting surface 570a. Here, the base and emitting surface are matched by having the diameter “d” of the circular base 550a equal to the diagonal dimension (also “d”) of the square emitting surface 570a. In FIG. 20b, an optical element having a hexagonal base 550b is optically coupled to an LED component having a square emitting surface 570b. Here, the height “h” of the hexagonal base 550b matches the height “h” of the square emitting surface 570b. In FIG. 20c, an optical element having a rectangular base 550c is optically coupled to an LED component having a square emitting surface 570c. Here, the width “w” of both the base and the emitting surface are matched. In FIG. 20d, an optical element having a square base 550d is optically coupled to an LED component having a hexagonal emitting surface 570d. Here, the height “h” of both the base and the emitting surface are matched. Of course, a simple arrangement, in which both the base and emitting surface are identically shaped and have the same surface area, also meets this criteria. Here, the surface area of the base is matched to the surface area of the emitting surface of the LED component.

Similarly, when an optical element is coupled to an array of LED components, the size of the array at the emitting surface side preferably can be matched to the size of the base of the optical element. Again, the shape of the array need not match the shape of the base, as long as they are matched in at least one dimension (e.g. diameter, width, height, or surface area).

Alternatively, the size of the LED component at the emitting surface or the combined size of the LED component array can be smaller or larger than the size of the base. FIGS. 19a and 19c show embodiments in which the emitting surface (412a and 412c, respectively) of the LED component (410a and 410c, respectively) is matched to the size of the base (422a and 422c, respectively). FIG. 19b shows an LED component 410b having an emitting surface 412b that is larger than the base 422b. FIG. 19d shows an array 412d of LED components, the array having a combined size at the emitting surface 412d that is larger than the size of the base 422d. FIG. 19e shows an LED component 410e having an emitting surface 412e that is smaller than the base 422e.

For example, if the LED component emitting surface is a square having sides of 1 mm, the optical element base can be made having a matching square having a 1 mm side. Alternatively, a square emitting surface could be optically coupled to a rectangular base, the rectangle having one of its sides matched in size to the size of the emitting surface side. The non-matched side of the rectangle can be larger or smaller than the side of the square. Optionally, an optical element can be made having a circular base having a diameter equal to the diagonal dimension of the emitting surface. For example, for a 1 mm by 1 mm square emitting surface a circular base having a diameter of 1.41 mm would be considered matched in size for the purpose of this application. The size of the base can also be made slightly smaller than the size of the emitting surface. This can have advantages if one of the goals is to minimize the apparent size of the light source, as described in commonly owned U.S. Patent Application Publication 2006/0091411 (Ouderkirk et al.), “High Brightness LED Package”.

FIG. 21 shows another embodiment of a light source comprising a converging optical element 624 optically coupled to a plurality of LED components 614a-c arranged in an array 612. This arrangement can be particularly useful when red, green, and blue LEDs are combined in the array to produce white light when mixed. In FIG. 21, the optical element 624 has converging sides 646 to redirect light to the sides. The optical element 624 has a base 624 shaped as a square, which is optically coupled to the array of LED components 612. The array of LED components 612 also forms a square shape (having sides 616).

Optical elements disclosed herein can be manufactured by conventional means or by using precision abrasive techniques disclosed in commonly assigned U.S. Patent Application Publication 2006/0094340 (Ouderkirk et al.), “PROCESS FOR MANUFACTURING OPTICAL AND SEMICONDUCTOR ELEMENTS”, U.S. Patent Application Publication 2006/0094322 (Ouderkirk et al.), “PROCESS FOR MANUFACTURING A LIGHT EMITTING ARRAY”, and U.S. patent application Ser. No. 11/288071, “ARRAYS OF OPTICAL ELEMENTS AND METHOD OF MANUFACTURING SAME” (Attorney Docket No. 60914US002), filed Nov. 22, 2005.

The disclosed optical elements (including particularly extractors) are transparent and preferably have a relatively high refractive index. Suitable materials for the optical element include without limitation inorganic materials such as high index glasses (e.g. Schott glass type LASF35, available from Schott North America, Inc., Elmsford, N.Y. under a trade name LASF35) and ceramics (e.g. sapphire, zinc oxide, zirconia, diamond, and silicon carbide). Sapphire, zinc oxide, diamond, and silicon carbide are particularly useful since these materials also have a relatively high thermal conductivity (0.2-5.0 W/cm K). High index polymers or nanoparticle filled polymers are also contemplated. Suitable polymers can be both thermoplastic and thermosetting polymers. Thermoplastic polymers can include polycarbonate and cyclic olefin copolymer. Thermosetting polymers can be for example acrylics, epoxy, silicones and others known in the art. Suitable ceramic nanoparticles include zirconia, titania, zinc oxide, and zinc sulfide.

The index of refraction of the optical element (nₒ) is preferably similar to the index of LED component emitting surface (nₑ). Preferably, the difference between the two is no greater than 0.2 (|nₒ−nₑ|<0.2). Optionally, the difference can be greater than 0.2, depending on the materials used. For example, the emitting surface can have an index of refraction of 1.75. A suitable optical element can have an index of refraction equal to or greater than 1.75 (nₒ≧1.75), including for example nₒ≧1.9, nₒ≧2.1, and nₒ≧2.3. Optionally, nₒ can be lower than nₑ (e.g. nₒ≧1.7). Preferably, the index of refraction of the optical element is matched to the index of refraction of the primary emitting surface. In some embodiments, the indexes of refraction of both the optical element and the emitting surface can be the same in value (nₒ=nₑ). For example, a sapphire emitting surface having nₑ=1.76 can be matched with a sapphire optical element, or a glass optical element of SF4 (available from Schott North America, Inc., Elmsford, N.Y. under a trade name SF4) nₒ=1.76. In other embodiments, the index of refraction of the optical element can be higher or lower than the index of refraction of the emitting surface. When made of high index materials, optical elements increase light extraction from the LED component due to their high refractive index and modify the emission distribution of light due to their shape, thus providing a tailored light emission pattern.

Throughout this disclosure, the LED component 12 is depicted generically for simplicity, but can include conventional design features as known in the art in addition to the re-emitting structures described above. For example, the LED component can include distinct p- and n-doped semiconductor layers, buffer layers, substrate layers, and superstrate layers. A simple rectangular LED component arrangement is shown, but other known configurations are also contemplated, e.g., angled side surfaces forming a truncated inverted pyramid LED component shape. Electrical contacts to the LED component are also not shown for simplicity, but can be provided on any of the surfaces of the die as is known. In exemplary embodiments the LED component has two contacts both disposed at the bottom surface in a “flip chip” design. The present disclosure is not intended to limit the shape of the optical element or the shape of the LED component, but merely provides illustrative examples.

An optical element is considered optically coupled to, or in optical contact with, an LED component, when the minimum gap between the optical element and emitting surface of the LED component is no greater than the evanescent wave. Optical coupling can be achieved by placing the LED component and the optical element physically close together. FIG. 14 shows a gap 150 between the emitting surface 12a of the LED component 12 and the base 120 of optical element 99. Typically, the gap 150 is an air gap and is typically very small to promote frustrated total internal reflection. For example, in FIG. 14, the base 120 of the optical element 99 is optically close to the emitting surface 12a of the LED component 12, if the gap 150 is on the order of the wavelength of light in air. Preferably, the thickness of the gap 150 is less than a wavelength of light in air. In LEDs where multiple wavelengths of light are used, the gap 150 is preferably at most the value of the longest wavelength. Suitable gap sizes include 25 nm, 50 nm, and 100 nm. Preferably, the gap is minimized, such as when the LED component and the input aperture or base of the optical element are polished to optical flatness and wafer bonded together.

In addition, it is preferred that the gap 150 be substantially uniform over the area of contact between the emitting surface 12a and the base 120, and that the emitting surface 12a and the base 120 have a roughness of less than 20 nm, preferably less than 5 nm. In such configurations, a light ray emitted from LED component 12 outside the escape cone or at an angle that would normally be totally internally reflected at the LED component-air interface will instead be transmitted into the optical element 20. To promote optical coupling, the surface of the base 120 can be shaped to match the emitting surface 12a. For example, if the emitting surface 12a of LED component 12 is flat, as shown in FIG. 14, the base 120 of optical element 99 can also be flat. Alternatively, if the emitting surface of the LED component is curved (e.g. slightly concave) the base of the optical element can be shaped to mate with the emitting surface (e.g. slightly convex). The size of the base 120 may either be smaller, equal, or larger than LED component emitting surface 12a. The base 120 can be the same or different in cross sectional shape than LED component 12. For example, the LED component can have a square emitting surface while the optical element has a circular base. Other variations will be apparent to those skilled in the art.

Suitable gap sizes include 100 nm, 50 nm, and 25 nm. Preferably, the gap is minimized, such as when the LED component and the input aperture or base of the optical element are polished to optical flatness and wafer bonded together. The optical element and LED component can be bonded together by applying high temperature and pressure to provide an optically coupled arrangement. Any known wafer bonding technique can be used. Exemplary wafer bonding techniques are described in U.S. Patent Application Publication 2006/0094340 (Ouderkirk et al.), “Process for Manufacturing Optical and Semiconductor Elements”.

In case of a finite gap, optical coupling can be achieved or enhanced by adding a thin optically conducting layer between the emitting surface of the LED component and the base of the optical element. FIG. 22 shows a partial schematic side view of an optical element and LED component, such as that shown in FIG. 14, but with a thin optically conducting layer 660 disposed within the gap 150. Like the gap 150, the optically conducting layer 660 can be 100 nm, 50 nm, 25 nm in thickness or less. Preferably, the refractive index of the optically coupling layer is closely matched to the refractive index of the emission surface or the optical element. An optically conducting layer can be used in both bonded and non-bonded (mechanically decoupled) configurations. In bonded embodiments, the optically conducting layer can be any suitable bonding agent that transmits light, including, for example, a transparent adhesive layer, inorganic thin films, fusable glass frit or other similar bonding agents. Additional examples of bonded configurations are described, for example, in U.S. Patent Publication No. U.S. 2002/0030194 “Light Emitting Diodes with Improved Light Extraction Efficiency” (Camras et al.) published Mar. 14, 2002.

In non-bonded embodiments, an LED component can be optically coupled to the optical element without use of any adhesives or other bonding agents between the LED component and the optical element. Non-bonded embodiments allow both the LED component and the optical element to be mechanically decoupled and allowed to move independently of each other. For example, the optical element can move laterally with respect to the LED component. In another example both the optical element and the LED component are free to expand as each component becomes heated during operation. In such mechanically decoupled systems the majority of stress forces, either sheer or normal, generated by expansion are not transmitted from one component to another component. In other words, movement of one component does not mechanically affect other components. This configuration can be particularly desirable where the light emitting material is fragile, where there is a coefficient of expansion mismatch between the LED component and the optical element, and where the LED is being repeatedly turned on and off.

Mechanically decoupled configurations can be made by placing the optical element optically close to the LED component (with only a very small air gap between the two). The air gap should be small enough to promote frustrated total internal reflection, as described above.

Alternatively, as shown in FIG. 22, a thin optically conducting layer 660 (e.g. an index matching fluid) can be added in the gap 150 between the optical element 99 and the LED component 12, provided the optically conducting layer allows the optical element and LED component to move independently. Examples of materials suitable for the optically conducting layer 660 include index matching oils, and other liquids or gels with similar optical properties. Optionally, optically conducting layer 660 can also be thermally conducting.

The optical element and LED component can be encapsulated together using any of the known encapsulant materials, to make a final LED package or light source. Encapsulating the optical element and LED component provides a way to hold them together in the non-bonded embodiments.

Additional non-bonded configurations are described in commonly owned U.S. Patent Application Publication 2006/0091784 (Connor et al.), “LED Package with Non-bonded Optical Element”.

The optical element can be made from a single structure, for example cut from a single block of material, or can be made by joining two or more sections together in a compound construction.

A first section desirably makes optical contact with the LED component, and is made of a first optical material having a high refractive index (preferably about equal to the LED component refractive index at the emitting surface), and optionally high thermal conductivity, and/or high thermal stability. In this regard, high thermal stability refers to materials having a decomposition temperature of about 600° C. or more. The thickness of the first section is preferably optically thick (e.g. effectively at least 5 microns, or 10 times the wavelength of light).

Silicon carbide is also electrically conductive, and as such may also provide an electrical contact or circuit function. Scattering within optical elements may be acceptable if the scattering is limited to a position near the input end or base of the optical element. However, it would be expensive and time consuming to make an optical element with sufficient length to efficiently couple light from an LED component. An additional challenge in making one-piece optical elements is that the material yield may be relatively low, and the form-factor may force the LED component to be individually assembled with the optical element. For these reasons, it can be advantageous to divide the optical element into two (or more) sections, the sections being made of different optical materials, to reduce manufacturing cost.

A second section is joined to the first section and is made of a second optical material, which may have lower material costs and be more easily fabricated than the first optical material. The second optical material may have a lower refractive index, lower thermal conductivity, or both relative to the first optical material. For example, the second optical material can comprise glasses, polymers, ceramics, ceramic nanoparticle-filled polymers, and other optically clear materials. Suitable glasses include those comprising oxides of lead, zirconium, titanium, and barium. The glasses can be made from compounds including titanates, zirconates, and stannates. Suitable ceramic nanoparticles include zirconia, titania, zinc oxide, and zinc sulfide.

Optionally, a third section composed of a third optical material can be joined to the second section to further aid in coupling the LED light to the outside environment. In one embodiment the refractive indices of the three sections are arranged such that n₁>n₂>n₃ to minimize overall Fresnel surface reflections associated with the optical element.

The disclosed light sources may be a component or the critical component of a graphic display device such as a large- or small-screen video monitor, computer monitor or display, television, telephone device or telephone device display, personal digital assistant or personal digital assistant display, pager or pager display, calculator or calculator display, game or game display, toy or toy display, large or small appliance or large or small appliance display, automotive dashboard or automotive dashboard display, automotive interior or automotive interior display, marine dashboard or marine dashboard display, marine interior or marine interior display, aeronautic dashboard or aeronautic dashboard display, aeronautic interior or aeronautic interior display, traffic control device or traffic control device display, advertising display, advertising sign, or the like.

The disclosed light sources may be a component or the critical component of a liquid crystal display (LCD), or like display, as a backlight to that display. In some embodiments, the semiconductor device is specially adapted for use a backlight for a liquid crystal display by matching the colors emitted by the semiconductor device to the color filters of the LCD display.

The disclosed light sources may be a component or the critical component of an illumination device such as a free-standing or built-in lighting fixture or lamp, landscape or architectural illumination fixture, hand-held or vehicle-mounted lamp, automotive headlight or taillight, automotive interior illumination fixture, automotive or non-automotive signaling device, road illumination device, traffic control signaling device, marine lamp or signaling device or interior illumination fixture, aeronautic lamp or signaling device or interior illumination fixture, large or small appliance or large or small appliance lamp, or the like; or any device or component used as a source of infrared, visible, or ultraviolet radiation.

In some cases, a light source includes: (a) an LED that is capable of emitting light at a first wavelength; (b) a re-emitting semiconductor construction that includes a potential well that is not located within a pn junction, where the re-emitting semiconductor construction has an emitting surface; (c) a patterned low index layer in optical contact with a first portion of the emitting surface, where the patterned layer has a first refractive index; and (d) an optical element that has an input surface in optical contact with a second portion of the emitting surface, where the optical element has a second refractive index higher than the first refractive index. In some cases, the patterned low index layer provides total internal reflection at the emitting surface for at least some light generated within the light source.

In some cases, a light source includes: (a) an LED component that includes: (i) an LED that is capable of emitting light at a first wavelength; and (ii) a re-emitting semiconductor construction which includes a potential well not located within a pn junction, where the re-emitting semiconductor construction has an emitting surface; (b) means for totally internally reflecting at least some of the light generated by the LED component back into the LED component, where the reflecting means is in optical contact with a first portion of the emitting surface; and (c) an optical element that has an input surface in optical contact with a second portion of the emitting surface different from the first portion.

In some cases, a light source includes: (a) an LED component that includes: (i) an LED that is capable of emitting light at a first wavelength; and (ii) a re-emitting semiconductor construction that includes a potential well not located within a pn junction, where the re-emitting semiconductor construction has an emitting surface; and (b) a collimating optical element that has an input surface and an output surface. In some cases, the input surface is in optical contact with at least a portion of the emitting surface. In some cases, the optical element includes a first portion that includes the input surface and is composed of a first material. In some cases, the optical element includes a second portion that includes the output end and is composed of a second material. In some cases, the first material has a refractive index greater than that of the second material. In some cases, the first portion has a thermal conductivity greater than that of the second material.

In some cases, a light source includes: (a) an LED component that includes: (i) an LED that is capable of emitting light at a first wavelength; and (ii) a re-emitting semiconductor construction which includes a second potential well not located within a pn junction, where the re-emitting semiconductor construction has an emitting surface; and (b) a plurality of optical elements, where each such optical element has an input surface. In some cases, the optical elements are sized such that the input surfaces are spaced apart from each other and are in optical contact with different portions of the emitting surface.

In some cases, a light source includes: (a) an LED component that includes a first potential well located within a pn junction and a second potential well not located within a pn junction, where the LED component has an emitting surface; (b) a patterned low index layer that is in optical contact with a first portion of the emitting surface, where the patterned layer has a first refractive index; and (c) an optical element that has an input surface in optical contact with a second portion of the emitting surface. In some cases, the optical element has a second refractive index that is higher than the first refractive index. In some cases, the patterned low index layer provides total internal reflection at the emitting surface for at least some light generated within the light source.

In some cases, a light source includes: (a) an LED component that includes a first potential well located within a pn junction and a second potential well not located within a pn junction, where the LED component has an emitting surface; (b) means for totally internally reflecting at least some of the light generated by the LED component back into the LED component, where the reflecting means is in optical contact with a first portion of the emitting surface; and (c) an optical element that has an input surface in optical contact with a second portion of the emitting surface different from the first portion.

In some cases, a light source includes: (a) an LED component that includes a first potential well located within a pn junction and a second potential well not located within a pn junction, where the LED component has an emitting surface; and (b) a collimating optical element that has an input surface and an output surface. In some cases, the input surface is in optical contact with at least a portion of the emitting surface. In some cases, the optical element includes a first portion that includes the input surface and is composed of a first material. In some cases, the optical element includes a second portion that includes the output surface and is composed of a second material. In some cases, the first material has a refractive index greater than that of the second material. In some cases, the first material has a thermal conductivity greater than that of the second material.

In some cases, a light source includes: (a) an LED component that includes a first potential well located within a pn junction and a second potential well not located within a pn junction, where the LED component has an emitting surface; and (b) a plurality of optical elements, where each such optical element has an input surface. In some cases, the optical elements are sized such that the input surfaces are spaced apart from each other and are in optical contact with different portions of the emitting surface.

In some cases, a light source includes: (a) an LED that is capable of emitting light at a first wavelength and has an emitting surface; (b) a re-emitting semiconductor construction that includes a potential well not located within a pn junction; (c) a patterned low index layer in optical contact with a first portion of the emitting surface, that the patterned layer has a first refractive index; and (d) an optical element that has an input surface in optical contact with a second portion of the emitting surface. In some cases, the optical element has a second refractive index higher than the first refractive index. In some cases, the patterned low index layer provides total internal reflection at the emitting surface for at least some light generated within the light source.

In some cases, a light source includes: (a) and LED component that includes: (i) an LED that is capable of emitting light at a first wavelength and has an emitting surface; and (ii) a re-emitting semiconductor construction that includes a potential well not located within a pn junction; (b) means for totally internally reflecting at least some of the light generated by the LED component back into the LED component, where the reflecting means is in optical contact with a first portion of the emitting surface; and (c) an optical element that has an input surface in optical contact with a second portion of the emitting surface different from the first portion.

In some cases, a light source includes: (a) an LED component that includes: (i) an LED that is capable of emitting light at a first wavelength and has an emitting surface; and (ii) a re-emitting semiconductor construction that includes a potential well not located within a pn junction; and (b) a collimating optical element that has an input surface and an output surface. In some cases, the input surface is in optical contact with at least a portion of the emitting surface. In some cases, the optical element includes a first portion that includes the input surface and is composed of a first material. In some cases, the optical element includes a second portion that includes the output surface and is composed of a second material. In some cases, the first material has a refractive index greater than that of the second material. In some cases, the first material has a thermal conductivity greater than that of the second material.

In some cases, a light source includes: (a) an LED component that includes: (i) an LED that is capable of emitting light at a first wavelength and has an emitting surface; and (ii) a re-emitting semiconductor construction that includes a potential well not located within a pn junction; and (b) a plurality of optical elements, where each optical element has an input surface. In some cases, the optical elements are sized such that the input surfaces are spaced apart from each other and are in optical contact with different portions of the emitting surface.

In some cases, a light source includes (a) an LED that is capable of emitting light at a first wavelength; (b) a re-emitting semiconductor construction that includes a potential well not located within a pn junction and has an emitting surface; and (c) a light extractor that has an input surface in optical contact with the emitting surface.

In some cases, a light source includes: (a) an LED component that includes a first potential well located within a pn junction and a second potential well not located within a pn junction, where the LED component has an emitting surface; and (b) a light extractor that has an input surface in optical contact with the emitting surface.

In some cases, a light source includes: (a) an LED that is capable of emitting light at a first wavelength and has an emitting surface; (b) a re-emitting semiconductor construction that includes a potential well not located within a pn junction; and (c) a light extractor that has an input surface in optical contact with the emitting surface.

In some cases, a light source includes: (a) an LED that is capable of emitting light at a first wavelength; (b) a re-emitting semiconductor construction that includes a potential well not located within a pn junction and has an emitting surface; and (c) a patterned low index layer in optical contact with a first portion of the emitting surface which is less than all of the emitting surface. In some cases, the patterned layer has a refractive index lower than that of the emitting surface.

In some cases, a light source includes: (a) an LED component that includes a first potential well located within a pn junction and a second potential well not located within a pn junction, where the LED component has an emitting surface; and (b) a patterned low index layer in optical contact with a first portion of the emitting surface which is less than all of the emitting surface. In some cases, the patterned layer has a refractive index lower than that of the emitting surface.

In some cases, a light source includes: (a) an LED that is capable of emitting light at a first wavelength and has an emitting surface; (b) a re-emitting semiconductor construction that includes a potential well not located within a pn junction; and (c) a patterned low index layer in optical contact with a first portion of the emitting surface which is less than all of the emitting surface. In some cases, the patterned layer has a refractive index lower than that of the emitting surface. In some cases, a graphic display device or an illumination device includes the light source.

Various modifications and alterations of this invention will become apparent to those skilled in the art without departing from the scope and principles of this invention, and it should be understood that this invention is not to be unduly limited to the illustrative embodiments set forth hereinabove.

We claim:

1. A light source, comprising:
an LED component having an emitting surface and including an LED and a re-emitting semiconductor construction, the LED being capable of emitting light at a first wavelength, and the re-emitting semiconductor construction including a second potential well not located within a pn junction; and
an optical element having an input surface and an output surface, the input surface being in optical contact with at least a portion of the emitting surface.

2. The light source of claim 1, wherein the second potential well is or includes a quantum well.

3. The light source of claim 1, wherein the LED includes a first potential well located within a pn junction.

4. The light source of claim 1, wherein the emitting surface is a surface of an LED die, and wherein the optical element is disposed between the LED die and the re-emitting semiconductor construction.

5. The light source of claim 4, wherein the re-emitting semiconductor construction is bonded to the output surface of the optical element.

6. The light source of claim 1, wherein the emitting surface is a surface of the re-emitting semiconductor construction, and wherein the re-emitting semiconductor construction is disposed between the LED and the optical element.

7. The light source of claim 6, wherein the re-emitting semiconductor construction is attached to the LED by a bonding layer.

8. The light source of claim 6, wherein the re-emitting semiconductor construction and the LED have a unitary construction, formed on the same semiconductor wafer.

9. The light source of claim 1, wherein the optical element comprises an encapsulant.

10. The light source of claim 1, wherein the optical element comprises an extractor.

11. The light source of claim 1, wherein the optical element comprises a lens.

12. The light source of claim 1, further comprising a patterned low index layer in optical contact with a first portion of the emitting surface, the patterned layer having a first refractive index, and where the input surface of the optical element is in optical contact with a second portion of the emitting surface, the optical element having a second refractive index higher than the first refractive index.

13. The light source of claim 1, further comprising means for totally internally reflecting at least some of the light generated by the LED component back into the LED component, the reflecting means being in optical contact with a first portion of the emitting surface, and wherein the input surface of the optical element is in optical contact with a second portion of the emitting surface different from the first portion.

14. The light source of claim 1, wherein the optical element comprises a first portion that comprises the input surface and that is composed of a first material, and wherein the optical element comprises a second portion that comprises the output end and that is composed of a second material, and wherein the first material has a refractive index greater than that of the second material.

15. The light source of claim 1, wherein the optical element is one of a plurality of optical elements, each such optical element having an input surface; wherein the optical elements are sized such that the input surfaces are spaced apart from each other and are in optical contact with different portions of the emitting surface.

16. The light source of claim 1, wherein the optical element includes a base, two converging sides, and two diverging sides.

17. The light source of claim 1, wherein the optical element is shaped to direct light emitted by the LED component to produce a side emitting pattern.

18. The light source of claim 1, wherein the optical element includes a base, an apex smaller than the base, and a converging side extending between the base and the apex.

19. The light source of claim 18, wherein the base is the input surface of the optical element, and the base is no greater in size than the emitting surface of the LED component.

20. A graphic display device comprising the light source according to claim 1.

21. An illumination device comprising the light source according to claim 1.
